(19) United States
(12) Patent Application Publication
(10) Pub. No.: US 2025/0201756 A1
(43) Pub. Date: Jun. 19, 2025

(54) SEMICONDUCTOR DEVICE

(71) Applicant: FUJI ELECTRIC CO., LTD., Kawasaki-shi (JP)

(72) Inventor: Yushi SATO, Matsumoto-city (JP)

(73) Assignee: FUJI ELECTRIC CO., LTD., Kawasaki-shi (JP)

(21) Appl. No.: 19/064,292

(22) Filed: Feb. 26, 2025

Related U.S. Application Data
(63) Continuation of application No. PCT/JP2024/004504, filed on Feb. 9, 2024.

(30) Foreign Application Priority Data
Mar. 24, 2023 (JP) 2023-048803

(51) Int. Cl. H01L 23/00; H01L 21/48; H01L 23/498; H01L 25/065; H05K 1/02

(52) U.S. Cl. CPC H01L 24/48; H01L 24/32; H01L 24/49; H01L 24/73; H01L 25/0655; H01L 21/4853; H01L 21/4875; H01L 23/49838; H01L 24/45; H01L 2224/32225; H01L 2224/45124; H01L 2224/45144; H01L 2224/45147; H01L 2224/4805; H01L 2224/48247; H01L 2224/49175; H01L 2224/73215; H01L 2224/73265; H01L 2924/3512; H05K 1/0203

(57) ABSTRACT

A semiconductor device, including: a semiconductor chip; and a substrate having a front surface, and a rear surface opposite to the front surface and facing downward. The substrate is warped in a downward convex shape that defines a vertex of the warping. The substrate has a wiring board at the front surface thereof, the wiring board having a bonding area defined on an upper surface thereof, which is tilted due to the warping of the substrate. The bonding area has a support part provided therein. The semiconductor chip is bonded to the bonding area via a first bonding material, with an edge portion of the semiconductor chip closest to the vertex of the warping supported by the support part.

### CROSS-REFERENCE TO RELATED APPLICATION

This application is a continuation application of International Application PCT/JP2024/004504 filed on Feb. 9, 2024, which designated the U.S., which claims priority to Japanese Patent Application No. 2023-048803, filed on Mar. 24, 2023, the entire contents of which are incorporated herein by reference.

### BACKGROUND OF THE INVENTION

### 1. Field of the Invention

The embodiment discussed herein relates to a semiconductor device.

### 2. Background of the Related Art

A first semiconductor chip and a second semiconductor chip are bonded to a wiring part via a first solder part and a second solder part, respectively. The thickness of the first solder part is less than that of the second solder part. Therefore, in the case where an insulating substrate including the second semiconductor chip and wiring part is deformed due to thermal fluctuation, the second solder part is less likely to absorb the deformation, and thus cracks are likely to occur (see, for example,

Japanese Laid-open Patent Publication No. 2022-174923). In addition, in a configuration in which a semiconductor chip is bonded to a circuit pattern via a bonding material, a gentle projection without a sharp top is formed in an area of the circuit pattern facing the semiconductor chip. This improves a fatigue resistance of the bonding material (see, for example, Japanese Laid-open Patent Publication No. 2020-009995).

In a semiconductor device including a conductor layer and a semiconductor element bonded to the conductor layer via a solder layer, the solder layer has wire bumps therein. This enables the solder layer to have a uniform film thickness, which makes it possible to prevent the generation of voids in the solder layer (see, for example, Japanese Laid-open Patent Publication No. 2019-110317). In a mounting member that has a semiconductor chip soldered onto the mounting surface thereof, two areas with different wettability are provided around the semiconductor chip. This prevents a misalignment of the semiconductor chip including rotation (see, for example, Japanese Laid-open Patent Publication No. 2009-218280).

### SUMMARY OF THE INVENTION

According to one aspect, there is provided a semiconductor device, including: a semiconductor chip; and a substrate having a front surface, and a rear surface opposite to the front surface and facing downward, the substrate being warped in a downward convex shape that defines a vertex of the warping, the substrate having a wiring board at the front surface thereof, the wiring board having a bonding area defined on an upper surface thereof, which is tilted due to the warping of the substrate, wherein the bonding area has a support part provided therein, and the semiconductor chip is bonded to the bonding area via a first bonding material, with an edge portion of the semiconductor chip closest to the vertex of the warping supported by the support part.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to an embodiment;

FIG. 2 is a side view of the semiconductor device according to the embodiment;

FIG. 3 is a plan view of a semiconductor unit included in the semiconductor device according to the embodiment;

FIG. 4 is a plan view of an insulated circuit substrate included in the semiconductor device according to the embodiment;

FIG. 5 is a first side view of the semiconductor unit included in the semiconductor device according to the embodiment;

FIG. 6 is a second side view of the semiconductor unit included in the semiconductor device according to the embodiment;

FIG. 7 is a third side view of the semiconductor unit included in the semiconductor device according to the embodiment;

FIG. 8 is a fourth side view of the semiconductor unit included in the semiconductor device according to the embodiment;

FIG. 9 is a plan view (part 1) of the insulated circuit substrate included in the semiconductor device according to the embodiment and illustrates different warping;

FIG. 10 is a second side view (part 1) of the semiconductor unit with the different warping, which is included in the semiconductor device according to the embodiment;

FIG. 11 is a fourth side view (part 1) of the semiconductor unit with the different warping, which is included in the semiconductor device according to the embodiment;

FIG. 12 is a plan view (part 2) of the insulated circuit substrate included in the semiconductor device according to the embodiment and illustrates different warping;

FIG. 13 is a second side view (part 2) of the semiconductor unit with different warping, which is included in the semiconductor device according to the embodiment;

FIG. 14 is a fourth side view (part 2) of the semiconductor unit with different warping, which is included in the semiconductor device according to the embodiment;

FIG. 15 is a sectional view of the semiconductor device according to the embodiment;

FIG. 16 illustrates a back surface of a cooling device included in the semiconductor device according to the embodiment;

FIG. 17 is a flowchart illustrating a semiconductor device manufacturing method according to the embodiment;

FIG. 18 is a view for describing a structure obtained by a setting step included in the semiconductor device manufacturing method according to the embodiment;

FIG. 19 is a view for describing a structure obtained by the setting step of the semiconductor device manufacturing method according to a reference example;

FIG. 20 is a view for describing the first bonding step of the semiconductor device manufacturing method according to the reference example;

FIGS. 21A and 21B illustrate an insulated circuit substrate that is included in the semiconductor device according to the embodiment (Modification 1);

FIGS. 22A and 22B illustrate an insulated circuit substrate that is included in the semiconductor device according to the embodiment (Modification 2);

FIGS. 23A and 23B illustrate an insulated circuit substrate that is included in the semiconductor device according to the embodiment (Modification 3); and

FIGS. 24A and 24B illustrate an insulated circuit substrate that is included in the semiconductor device according to the embodiment (Modification 4).

### DETAILED DESCRIPTION OF THE INVENTION

Hereinafter, an embodiment will be described with reference to the accompanying drawings. In the following description, the terms “front surface” and “upper surface” refer to an X-Y plane facing up (in the +Z direction) in a semiconductor device 1 illustrated in drawings. Similarly, the term “up” refers to an upward direction (the +Z direction) in the semiconductor device 1 illustrated in the drawings. The terms “rear surface” and “lower surface” refer to an X-Y plane facing down (in the −Z direction) in the semiconductor device 1 illustrated in the drawings. Similarly, the term “down” refers to a downward direction (the −Z direction) in the semiconductor device 1 illustrated in the drawings. The same directionality applies to other drawings, as appropriate. The terms “front surface,” “upper surface,” “up,” “rear surface,” “lower surface,” “down,” and “side surface” are used for convenience to describe relative positional relationships, and do not limit the technical ideas of the embodiment. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately equal” may allow an error range of +10%. In addition, the expressions “being perpendicular” and “being parallel” may allow an error range of +10%.

### Embodiment

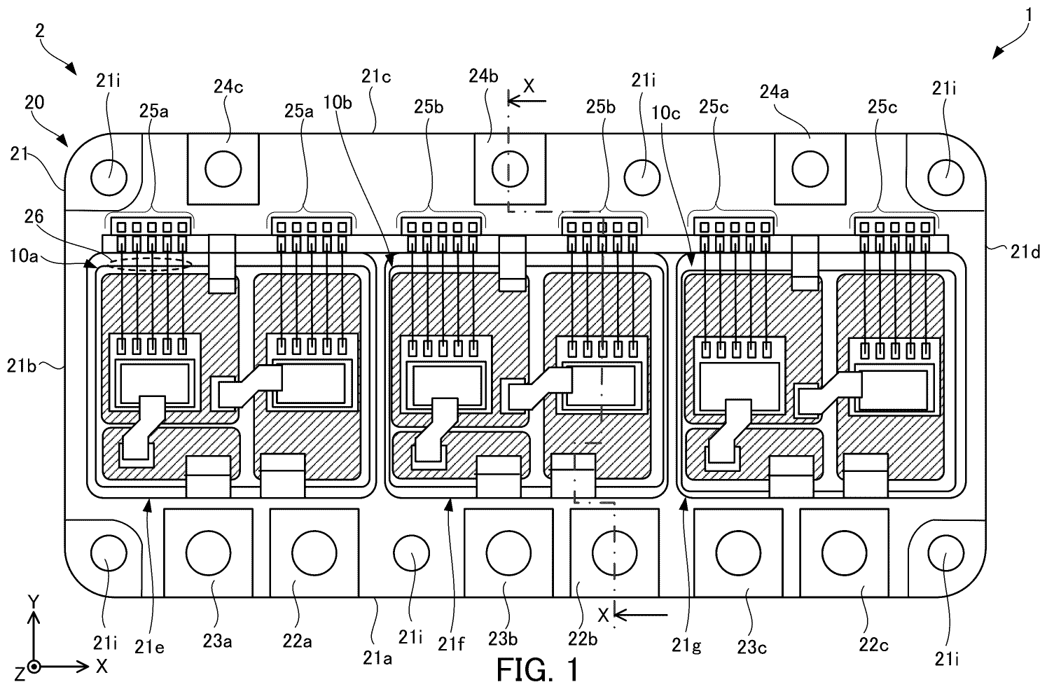

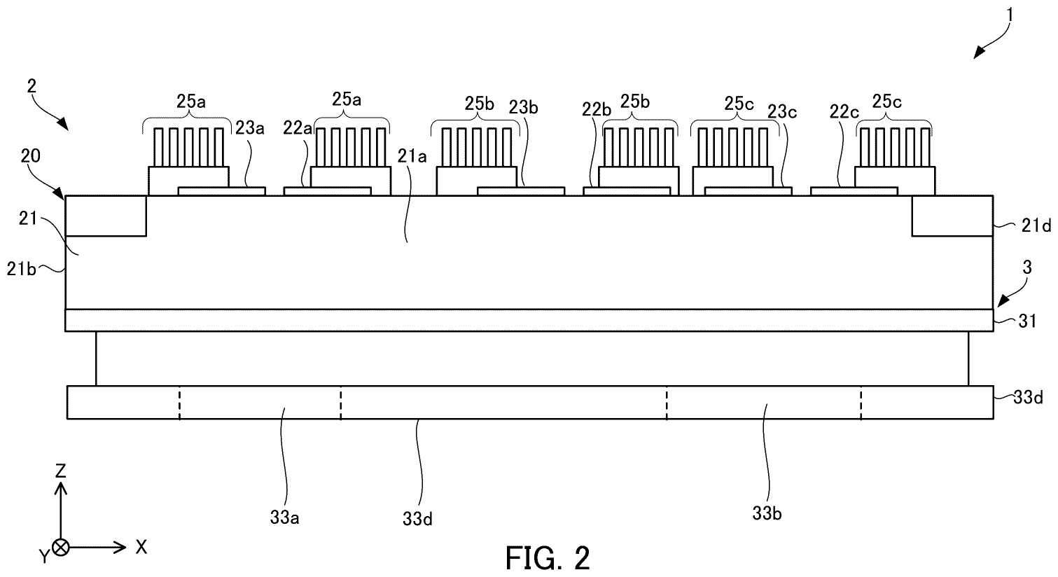

A semiconductor device 1 according to one embodiment will be described with reference to FIGS. 1 and 2. FIG. 1 is a plan view of the semiconductor device according to the embodiment. FIG. 2 is a side view of the semiconductor device according to the embodiment. In this connection, the side view of FIG. 2 is a view of the X-Z plane seen in the +Y direction in FIG. 1.

The semiconductor device 1 includes a semiconductor module 2 and a cooling device 3. The semiconductor module 2 includes semiconductor units 10a, 10b, and 10c and a housing 20 housing these semiconductor units 10a, 10b, and 10c. The semiconductor units 10a, 10b, and 10c housed in the housing 20 are sealed by a sealing member (not illustrated). In this connection, the semiconductor units 10a, 10b, and 10c have the same configuration. These semiconductor units 10a, 10b, and 10c may each or collectively be referred to as a semiconductor unit 10 without distinction among them. The semiconductor unit 10 will be described in detail later.

The housing 20 includes a frame 21, first connection terminals 22a, 22b, and 22c, second connection terminals 23a, 23b, and 23c, a U-phase output terminal 24a, a V-phase output terminal 24b, a W-phase output terminal 24c, and control terminals 25a, 25b, and 25c.

The frame 21 is substantially rectangular in plan view and has outer wall surfaces 21a, 21b, 21c, and 21d on the four sides thereof. In plan view, the outer wall surfaces 21a and 21c correspond to the long sides of the frame 21, and the outer wall surfaces 21b and 21d correspond to the short sides of the frame 21. In plan view, each corner where the outer wall surfaces 21a, 21b, 21c, and 21d meet does not necessarily have the right angle. The corners may be rounded, as illustrated in FIG. 1. A fixing hole 21i that penetrates through the frame 21 is formed in each corner of the front surface of the frame 21. In this connection, the fixing holes 21i formed in the corners of the frame 21 may be formed lower (in the −Z direction) than the front surface of the frame 21.

The frame 21 has unit housing spaces 21e, 21f, and 21g arranged along the outer wall surfaces 21a and 21c in the front surface. Each unit housing space 21e, 21f, and 21g is rectangular in plan view and is open. The semiconductor units 10a, 10b, and 10c are housed in the unit housing spaces 21e, 21f, and 21g, respectively. As will be described in detail later, the semiconductor units 10a, 10b, and 10c are joined to the top plate 31 of the cooling device 3, which will be described later. The frame 21 is attached to the top plate 31 of the cooling device 3. More specifically, the frame 21 is attached in such a manner that the unit housing spaces 21e, 21f, and 21g of the frame 21 surround (house) the semiconductor units 10a, 10b, and 10c disposed on the cooling device 3, respectively. In this connection, the cooling device 3 has an inlet 33a and an outlet 33b formed in the back surface 33d thereof (opposite to the top plate 31 to which the semiconductor units 10 are attached). The cooling device 3 will be described in detail later.

The frame 21 includes the first connection terminals 22a, 22b, and 22c and second connection terminals 23a, 23b, and 23c, which are arranged along the outer wall surface 21a on the side of the front surface of the frame 21 where the outer wall surface 21a is located in plan view.

One outer end of each of the first connection terminals 22a, 22b, and 22c and second connection terminals 23a, 23b, and 23c is exposed on the front surface of the frame 21, on the same side as the outer wall surface 21a. Their opposite inner ends are exposed inside the unit housing spaces 21e, 21f, and 21g and are electrically connected to the semiconductor units 10a, 10b, and 10c. In this connection, a nut may be provided at a position corresponding to the opening of each of the first connection terminals 22a, 22b, and 22c and second connection terminals 23a, 23b, and 23c in the front surface of the frame 21.

The frame 21 also includes the U-phase output terminal 24a, V-phase output terminal 24b, and W-phase output terminal 24c, which are arranged along the outer wall surface 21c on the side of the front surface of the frame 21 where the outer wall surface 21c is located. One outer end of each of the U-phase output terminal 24a, V-phase output terminal 24b, and W-phase output terminal 24c is exposed on the front surface of the frame 21, on the same side as the outer wall surface 21c. Their opposite inner ends are exposed inside the unit housing spaces 21e, 21f, and 21g and are electrically connected to the semiconductor units 10a, 10b, and 10c.

As described above, on the front surface of the frame 21 in plan view, the first connection terminal 22a and second connection terminal 23a and the W-phase output terminal 24c are located with the unit housing space 21e therebetween. Likewise, the first connection terminal 22b and second connection terminal 23b and the V-phase output terminal 24b are located with the unit housing space 21f therebetween. The first connection terminal 22c and second connection terminal 23c and the U-phase output terminal 24a are located with the unit housing space 21g therebetween.

Furthermore, the frame 21 includes the control terminals 25a, 25b, and 25c, which are arranged along the outer wall surface 21c on the +Y-direction side of the unit housing spaces 21e, 21f, and 21g in plan view. Each control terminal 25a, 25b, and 25c has two parts that are provided separately. For example, each control terminal 25a, 25b, and 25c is formed in L shape with an outer end and an inner end. The outer ends of the control terminals 25a, 25b, and 25c extend vertically upward (in the +Z direction) from the front surface of the frame 21. The inner ends of the control terminals 25a, 25b, and 25c are exposed inside the unit housing spaces 21e, 21f, and 21g. In this connection, the shape and quantity of the control terminals 25a, 25b, and 25c are not limited thereto but may be changed as appropriate.

The above-described frame 21 is integrally formed with the first connection terminals 22a, 22b, and 22c, second connection terminals 23a, 23b, and 23c, U-phase output terminal 24a, V-phase output terminal 24b, W-phase output terminal 24c, and control terminals 25a, 25b, and 25c by injection molding using a thermoplastic resin. Examples of the thermoplastic resin include a polyphenylene sulfide resin, a polybutylene terephthalate resin, a polybutylene succinate resin, a polyamide resin, and an acrylonitrile butadiene styrene resin.

The first connection terminals 22a, 22b, and 22c, second connection terminals 23a, 23b, and 23c, U-phase output terminal 24a, V-phase output terminal 24b, W-phase output terminal 24c, and control terminals 25a, 25b, and 25c are made of a metal with high electrical conductivity.

Examples of the metal here include copper, aluminum, and an alloy containing at least one of these as its main component. The surfaces of the first connection terminals 22a, 22b, and 22c, second connection terminals 23a, 23b, and 23c, U-phase output terminal 24a, V-phase output terminal 24b, W-phase output terminal 24c, and control terminals 25a, 25b, and 25c may be plated. Examples of the plating material used here include nickel, a nickel-phosphorus alloy, and a nickel-boron alloy.

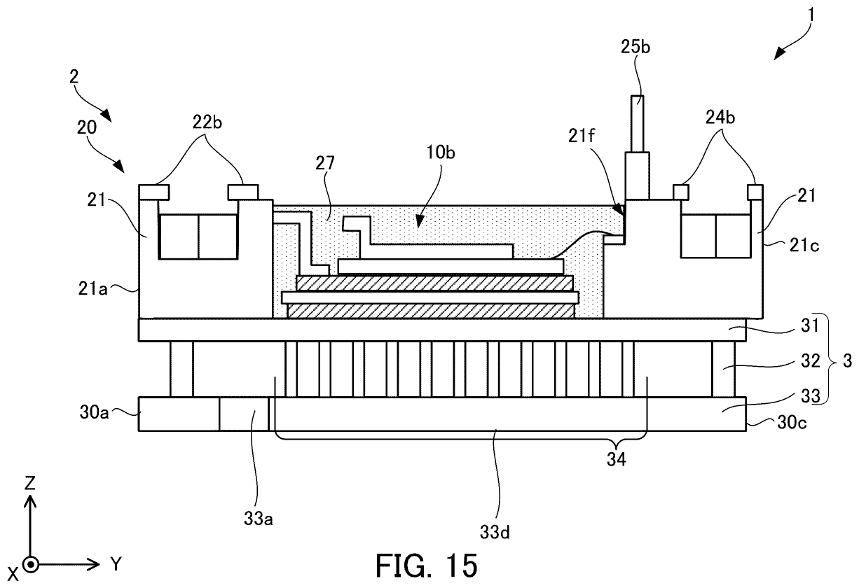

A sealing member 27 (see FIG. 15) that seals the unit housing spaces 21e, 21f, and 21g of the housing 20 may be a thermosetting resin. Examples of the thermosetting resin here include an epoxy resin, a phenolic resin, a maleimide resin, and a polyester resin. The epoxy resin is preferable. In addition, the sealing member 27 may contain a filler. The filler may be made of insulating ceramics with high thermal conductivity.

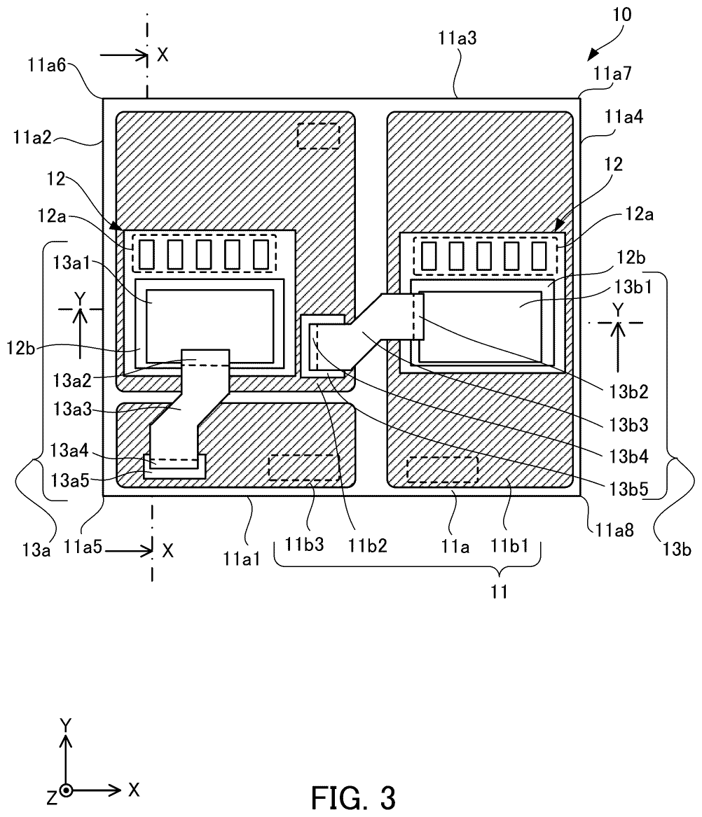

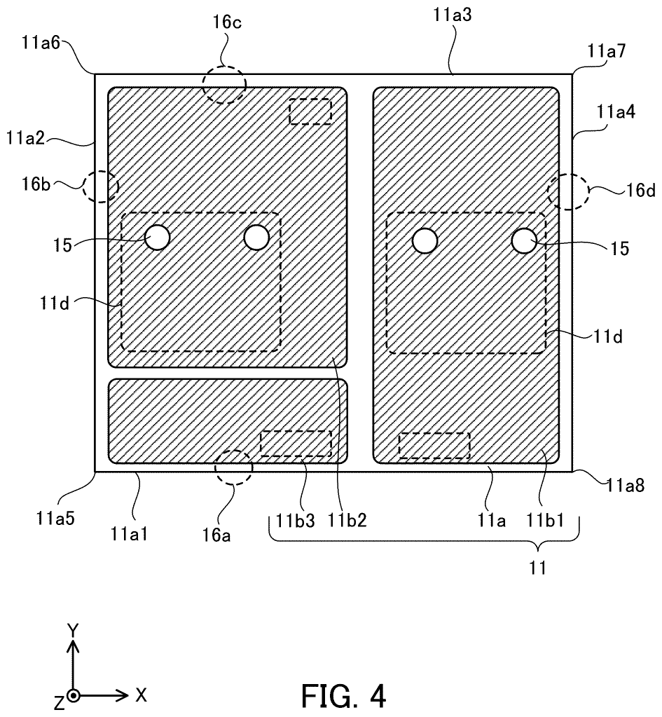

The following describes the semiconductor units 10a, 10b, and 10c with reference to FIGS. 3 and 4. FIG. 3 is a plan view of a semiconductor unit included in the semiconductor device according to the embodiment. FIG. 4 is a plan view of the insulated circuit substrate 11 of the semiconductor unit 10 of FIG. 3.

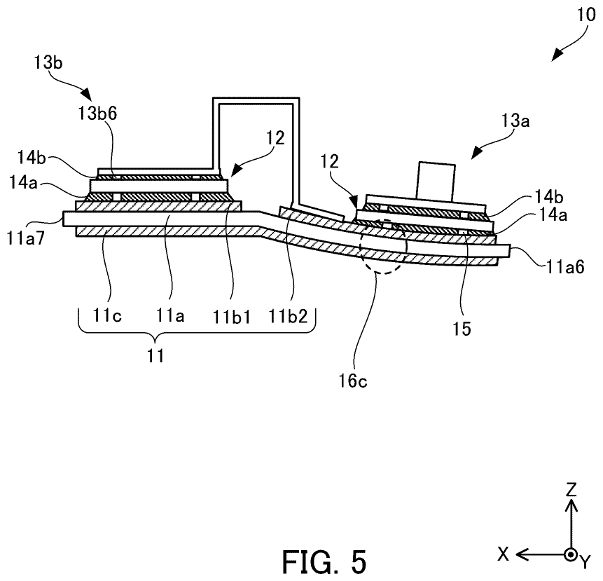

The semiconductor unit 10 includes an insulated circuit substrate 11 (substrate), two semiconductor chips 12, and lead frames 13a and 13b. The semiconductor chips 12 are bonded to the insulated circuit substrate 11 using a bonding material 14a (first bonding material) (see FIGS. 5 to 8). Each lead frame 13a and 13b is bonded to the main electrode on the front surface of a semiconductor chip 12 using a bonding material 14b (second bonding material) (see FIGS. 5 to 8).

The insulated circuit substrate 11 includes an insulating plate 11a and wiring boards 11b1, 11b2, and 11b3, as illustrated in FIG. 4, and also includes a metal plate 11c (see FIGS. 5 to 8). In addition, the insulated circuit substrate 11 includes support parts 15. In FIG. 4, areas (vertices 16a to 16d) indicated by broken lines indicate the positions of the vertices 16a to 16d of warping occurring in the insulated circuit substrate 11 in plan view. In the case where the vertices 16b and 16d of the warping occur, the support parts 15 are formed at the positions illustrated in FIG. 4. All the vertices 16a to 16d of the warping do not necessarily occur simultaneously at the illustrated positions. At least one vertex may occur. In addition, the positions of the vertices 16a to 16d of the warping in FIG. 4 are indicated just as an example. In this connection, other examples of the positions of vertices of warping that occur in the insulated circuit substrate 11 in plan view will be described later.

The insulating plate 11a and metal plate 11c are rectangular in plan view. The corners of the insulating plate 11a and metal plate 11c may be rounded or chamfered. In plan view, the metal plate 11c is smaller in size than the insulating plate 11a and is formed inside the insulating plate 11a.

The insulating plate 11a has side surfaces 11a1 to 11a4 on the four sides of the front surface thereof. The side surfaces 11a1 and 11a3 correspond to the long sides of the insulating plate 11a in plan view. The side surfaces 11a2 and 11a4 correspond to the short sides of the insulating plate 11a in plan view. The insulating plate 11a also has four corners 11a5 to 11a8. The corner 11a5 is formed by the side surfaces 11a1 and 11a2. The corner 11a6 is formed by the side surfaces 11a2 and 11a3. The corner 11a7 is formed by the side surfaces 11a3 and 11a4. The corner 11a8 is formed by the side surfaces 11a4 and 11a1. This insulating plate 11a is made of an insulating material with high thermal conductivity. The insulating plate 11a is made of ceramics. Examples of the ceramics here include aluminum oxide, aluminum nitride, and silicon nitride.

The wiring boards 11b1, 11b2, and 11b3 are formed on the front surface of the insulating plate 11a. The wiring boards 11b1, 11b2, and 11b3 are made of a metal with high electrical conductivity. Examples of the metal here include copper, aluminum, and an alloy containing at least one of these as its main component. In addition, the wiring boards 11b1, 11b2, and 11b3 have a thickness ranging from 0.1 mm to 2.0 mm, inclusive. The surfaces of the wiring boards 11b1, 11b2, and 11b3 may be plated to improve their corrosion resistance. Examples of the plating material used here include nickel, a nickel-phosphorus alloy, and a nickel-boron alloy.

The wiring board 11b1 occupies half the area of the front surface of the insulating plate 11a, the half area being located on the side where the side surface 11a4 is located and extending from the side surface 11a1 to the side surface 11a3. A bonding area 11d is defined on the upper surface of the wiring board 11b1. The bonding area 11d is where a semiconductor chip 12 is bonded and corresponds in shape to the semiconductor chip 12 in plan view. In addition, a dashed-line area indicated on the −Y-direction side of the upper surface of the wiring board 11b1 is where the inner end of a corresponding first connection terminal 22a, 22b, or 22c is joined. This joining may be achieved using a bonding material, laser welding, or ultrasonic welding. Alternatively, the inner end of the corresponding first connection terminal 22a, 22b, or 22c may be joined to the dashed-line area of the wiring board 11b1 via an electrically conductive block.

The wiring board 11b2 occupies half the area of the front surface of the insulating plate 11a, the half area being located on the side where the side surface 11a2 is located and extending from the side surface 11a3 to a point before the side surface 11a1. A bonding area 11d is defined on the upper surface of the wiring board 11b2. Support parts 15 are provided inside the bonding area 11d of the wiring board 11b2.

Each support part 15 has a projection shape. These support parts 15 may be columnar, for example. The term columnar here may include cylindrical, square-pillar, and triangular-pillar shapes, and also may include a truncated cone shape. A support part 15 is provided in each of the corners of the bonding areas 11d located on the side where the vertices 16b and 16d, to be described later, are located. A plurality of support parts 15 may be provided on the side of the bonding areas 11d where the vertices 16b and 16d, to be described later, are located. In this connection, the positions where the support parts 15 are provided depend on the positions of vertices of warping, as will be described later. FIG. 4 depicts the case where the support parts 15 are provided on the side of the bonding area 11d where the vertices 16b and 16d are located. In addition, there may be cases where the support parts 15 are not provided, depending on the positions of vertices of warping. The positions where the support parts 15 are provided, which depend on the positions of vertices of warping, will be described later.

The support parts 15 are preferably made of a metal with electrical conductivity. Examples of the metal here include copper, aluminum, and an alloy containing at least one of these as its main component. The support parts 15 may simply be disposed on the wiring board 11b2 or may integrally be joined to the wiring board 11b2. This allows the main electrode on the rear surface of the semiconductor chip 12 to be electrically connected to the wiring board 11b2. Furthermore, the support parts 15 may be sandwiched between the wiring board 11b2 and the rear surface of the semiconductor chip 12.

In addition, a dashed-line area indicated on the +Y-direction side of the upper surface of the wiring board 11b2 is where the inner end of a corresponding one of the U-phase output terminal 24a, V-phase output terminal 24b, and W-phase output terminal 24c is joined. This joining may be achieved using a bonding material, laser welding, or ultrasonic welding. Alternatively, the inner end of the corresponding one of the U-phase output terminal 24a, V-phase output terminal 24b, and W-phase output terminal 24c may be joined to the dashed-line area of the wiring board 11b2 via an electrically conductive block.

The wiring board 11b3 occupies an area that is surrounded by the wiring boards 11b1 and 11b2 on the front surface of the insulating plate 11a. A dashed-line area indicated in the wiring board 11b3 is where the end of a corresponding second connection terminal 23a, 23b, or 23c is joined. This joining may be achieved using a bonding material, laser welding, or ultrasonic welding.

Alternatively, the end of the corresponding second connection terminal 23a, 23b, or 23c may be joined to the dashed-line area of the wiring board 11b3 via an electrically conductive block.

These wiring boards 11b1, 11b2, and 11b3 are formed on the front surface of the insulating plate 11a in the following manner. A metal layer is formed on the front surface of the insulating plate 11a and is then processed by etching or another, to thereby form the wiring boards 11b1, 11b2, and 11b3 in predetermined shapes. Alternatively, the wiring boards 11b1, 11b2, and 11b3 cut out of a metal layer in advance may be press-bonded to the front surface of the insulating plate 11a. The corners of the wiring boards 11b1, 11b2, and 11b3 may be rounded or chamfered. The wiring boards 11b1, 11b2 and 11b3 are merely an example. The quantity, shapes, sizes, and positions of the wiring boards 11b1, 11b2, and 11b3 may desirably be determined according to necessity.

The metal plate 11c is formed on the rear surface of the insulating plate 11a, as illustrated in FIGS. 5 to 8. The metal plate 11c is rectangular. In plan view, the metal plate 11c is smaller in size than the insulating plate 11a and is larger in size than the area where the wiring boards 11b1, 11b2, and 11b3 are formed. The corners of the metal plate 11c may be rounded or chamfered. The metal plate 11c is smaller in size than the insulating plate 11a and is formed on the entire surface of the insulating plate 11a except the edge portion thereof. The metal plate 11c is made of a metal with high electrical conductivity. Examples of the metal here include copper, aluminum, and an alloy containing at least one of these. The surface of the metal plate 11c may be plated to improve its corrosion resistance. Examples of the plating material used here include nickel, a nickel-phosphorus alloy, and a nickel-boron alloy.

As the insulated circuit substrate 11 configured as above, a direct copper bonding (DCB) substrate or an active metal brazed (AMB) substrate may be used, for example. The insulated circuit substrate 11 may be attached to the front surface of the cooling device 3 via a bonding material (not illustrated). This allows heat generated by the semiconductor chips 12 to be transferred through the wiring boards 11b1 and 11b2, insulating plate 11a, and metal plate 11c to the cooling device 3 for dissipation.

The bonding materials 14a and 14b are solder. The solder is lead-free solder. The lead-free solder contains, as its main component, an alloy containing at least two selected from tin, silver, copper, zinc, antimony, indium, and bismuth. In addition, the solder may contain an additive. Examples of the additive include nickel, germanium, cobalt, and silicon. The solder containing the additive exhibits improved wettability, gloss, and bonding strength, which results in enhancing the reliability.

The bonding material (not illustrated) that bonds the semiconductor unit 10 and the cooling device 3 together may be solder, brazing material, and thermal interface material. The solder is lead-free solder. The brazing material contains, as its main component, at least one of an aluminum alloy, a titanium alloy, a magnesium alloy, a zirconium alloy, and a silicon alloy, for example. The thermal interface material is an adhesive such as an elastomer sheet, a room temperature vulcanization (RTV) rubber, a gel, or a phase change material, for example. The use of such a brazing material or thermal interface material for the attachment to the cooling device 3 improves the heat dissipation of the semiconductor unit 10.

A semiconductor chip 12 includes a power device element that is made of silicon. The semiconductor chip 12 has a thickness of 40 μm to 250 μm, inclusive, for example.

The power device element may be a reverse conducting-insulated gate bipolar transistor (RC-IGBT). The RC-IGBT has the functions of both IGBT serving as a switching element and freewheeling diode (FWD) serving as a diode element. The semiconductor chip 12 of this type has a control electrode 12a (gate electrode) and an output electrode (emitter electrode) that is a main electrode 12b on the front surface thereof. The semiconductor chip 12 also has an input electrode (collector electrode) that is a main electrode, not illustrated, on the rear surface thereof. In this connection, the control electrode 12a may be provided along one side (or at the center on the one side) on the front surface of the semiconductor chip 12. The output electrode is provided at the center of the front surface of the semiconductor chip 12. The input electrode may be provided in an area including the center of the rear surface of the semiconductor chip.

Instead of the RC-IGBT, the semiconductor chip 12 may use a set of switching element and diode element. The switching element may be, for example, an IGBT or a power metal-oxide-semiconductor field-effect transistor (MOSFET). For example, the semiconductor chip 12 of this type has an input electrode (drain electrode or collector electrode) as a main electrode on the rear surface thereof, and also has a control electrode 12a (gate electrode) and an output electrode (source electrode or emitter electrode) serving as a main electrode 12b on the front surface thereof. The diode element may be, for example, a Schottky barrier diode (SBD) or a P-intrinsic-N (PIN) diode, and these are used as FWDs. Such a semiconductor chip 12 has an output electrode (cathode electrode) as a main electrode on the rear surface thereof and also has an input electrode (anode electrode) as a main electrode on the front surface thereof.

Furthermore, the semiconductor chip 12 may include a power MOSFET as its switching element. This semiconductor chip 12 includes an FWD together with the power MOSFET. The semiconductor chip 12 of this type has a control electrode 12a (gate electrode) and an output electrode (source electrode) serving as a main electrode 12b on the front surface thereof. The semiconductor chip 12 also has an input electrode (drain electrode) serving as a main electrode on the rear surface thereof. Such a semiconductor chip 12 is preferably made of silicon carbide.

The lead frame 13a is wired to electrically connect the main electrode 12b of the semiconductor chip 12 (on the wiring board 11b2) to the wiring board 11b3. The lead frame 13b is wired to electrically connect the main electrode 12b of the semiconductor chip 12 (on the wiring board 11b1) to the wiring board 11b2. The semiconductor unit 10 may be a device that forms an inverter circuit for one phase.

The lead frames 13a and 13b integrally have main electrode bonding portions 13a1 and 13b1, first vertical connection portions 13a2 and 13b2, horizontal connection portions 13a3 and 13b3, second vertical connection portions 13a4 and 13b4, and wiring bonding portions 13a5 and 13b5, respectively. Each lead frame 13a and 13b has a uniform thickness throughout and is flat plate-shaped. The lead frames 13a and 13b may each be bent to form the above portions. The lead frames 13a and 13b are made of a metal with high electrical conductivity. Examples of the metal here include copper, aluminum, and an alloy containing at least one of these as its main component. The lead frames 13a and 13b have a thickness of 0.1 mm to 2.0 mm, inclusive.

The surfaces of the lead frames 13a and 13b may be plated to improve their corrosion resistance. Examples of the plating material used here include nickel, a nickel-phosphorus alloy, and a nickel-boron alloy.

The main electrode bonding portions 13a1 and 13b1 are flat plate-shaped. The main electrode bonding portions 13a1 and 13b1 are bonded to the main electrodes 12b of the semiconductor chips 12 (on the wiring boards 11b2 and 11b1) with the bonding material 14a. The main electrode bonding portions 13a1 and 13b1 are rectangular in plan view, as with the main electrodes 12b. Bosses 13a6 and 13b6 are formed on the rear surfaces of the main electrode bonding portions 13a1 and 13b1, respectively (see FIGS. 5 to 8). For example, the bosses 13a6 and 13b6 may be formed in the four corners of the rear surfaces of the respective rectangular main electrode bonding portions 13a1 and 13b1.

The lower ends of the first vertical connection portions 13a2 and 13b2 are integrally connected to ends of the main electrode bonding portions 13a1 and 13b1, respectively, and the upper ends thereof extend vertically upward (in the +Z direction) with respect to the main electrode bonding portions 13a1 and 13b1, respectively. The first vertical connection portion 13a2 is connected to the end of the main electrode bonding portion 13a1 located on the side where the wiring board 11b3 is located (i.e., located on the −Y-direction side), the main electrode bonding portion 13a1 being bonded to the semiconductor chip 12 disposed on the wiring board 11b2. The first vertical connection portion 13b2 is connected to the end of the main electrode bonding portion 13b1 located on the side where the wiring board 11b2 is located (i.e., located on the −X-direction side), the main electrode bonding portion 13b1 being bonded to the semiconductor chip 12 disposed on the wiring board 11b1.

The horizontal connection portions 13a3 and 13b3 are integrally connected to the upper ends of the first vertical connection portions 13a2 and 13b2 and extend in parallel to the wiring boards 11b3 and 11b2, respectively. The horizontal connection portions 13a3 and 13b3 are flat plate-shaped. The horizontal connection portions 13a3 and 13b3 extend in the ±Y and ±X directions, respectively. Each horizontal connection portion 13a3 and 13b3 may be offset in ±Y and/or ±X directions at one end relative to the other. In this configuration, the horizontal connection portion 13a3 spans the space between the wiring boards 11b2 and 11b3, and the horizontal connection portion 13b3 spans the space between the wiring boards 11b1 and 11b2. The horizontal connection portions 13a3 and 13b3 are parallel to the insulated circuit substrate 11 and may be level with each other. In order to form the above-described horizontal connection portions 13a3 and 13b3, the heights of the first vertical connection portions 13a2 and 13b2 and second vertical connection portions 13a4 and 13b4 are appropriately determined.

The upper ends of the second vertical connection portions 13a4 and 13b4 are integrally connected to ends of the horizontal connection portions 13a3 and 13b3, respectively, and the lower ends thereof extend vertically downward (in the −Z direction) and are integrally connected to the wiring bonding portions 13a5 and 13b5, respectively.

The wiring bonding portions 13a5 and 13b5 are bonded to the wiring boards 11b3 and 11b2 and are integrally connected to the lower ends of the second vertical connection portions 13a4 and 13b4, respectively.

The first vertical connection portion 13a2, horizontal connection portion 13a3 (except the bending portions), and second vertical connection portion 13a4 of the lead frame 13a have the same width. Note that the width here means the length in the direction (the ±X directions) perpendicular to the wiring direction (the ±Y directions) of the lead frame 13a.

The first vertical connection portion 13b2, horizontal connection portion 13b3 (except the bending portions), and second vertical connection portion 13b4 of the lead frame 13b have the same width. Note that the width here means the length in the direction (the ±Y directions) perpendicular to the wiring direction (the ±X directions) of the lead frame 13b.

The control electrodes 12a of the semiconductor chips 12 in the semiconductor units 10a, 10b, and 10c housed in the unit housing spaces 21e, 21f, and 21g of the housing 20 are mechanically and electrically connected to the inner ends of the control terminals 25a, 25b, and 25c by wires 26, respectively (see FIG. 1). The wires 26 are made of a material with high electrical conductivity as its main component. Examples of the material here include gold, copper, aluminum, and an alloy containing at least one of these. The wires 26 may preferably be an aluminum alloy containing a trace of silicon. In addition, the wires 26 have a diameter of 100 μm to 400 μm, inclusive, for example.

The semiconductor unit 10 configured as above is not flat because warping is caused in the insulated circuit substrate 11 by heating during the manufacturing process, which will be described later. For example, the warping depends on factors such as the volumes and formation locations of the wiring boards 11b1 to 11b3 and metal plate 11c in the insulated circuit substrate 11, the semiconductor chips 12, the lead frames 13a and 13b, and the heating temperature and time.

The following describes an example of warping caused in the insulated circuit substrate 11. In this example, the vertices 16a and 16c of the warping occur in the side surfaces 11a1 and 11a3 of the insulated circuit substrate 11, respectively. In addition, the vertices 16b and 16d of the warping occur in the side surfaces 11a2 and 11a4 of the insulated circuit substrate 11, respectively, on the side where the side surface 11a3 is located. This warping will be described with reference to FIGS. 5 to 8.

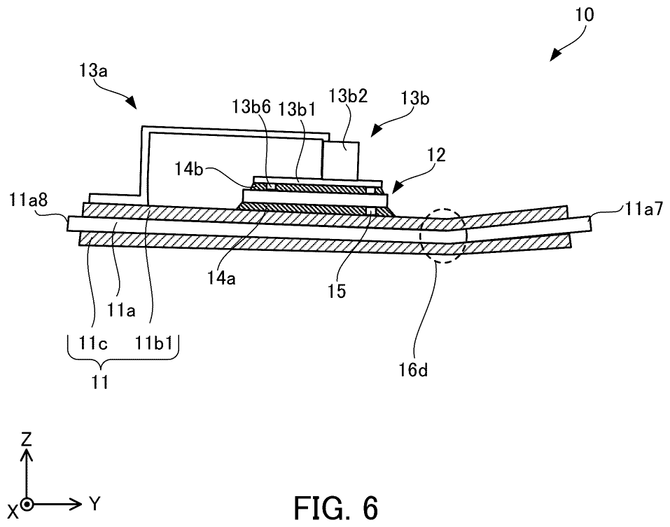

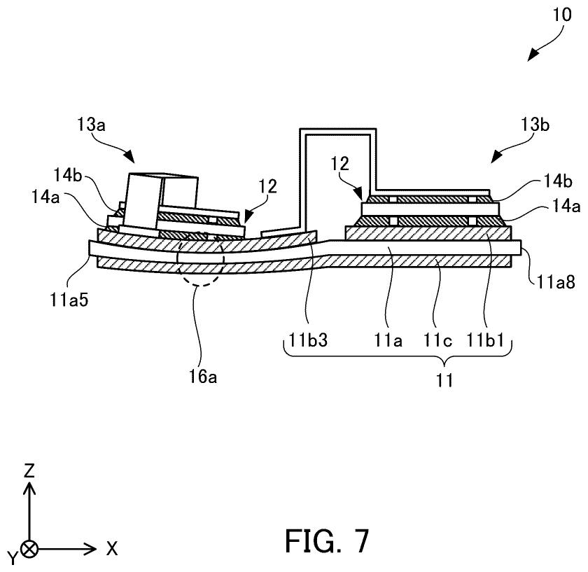

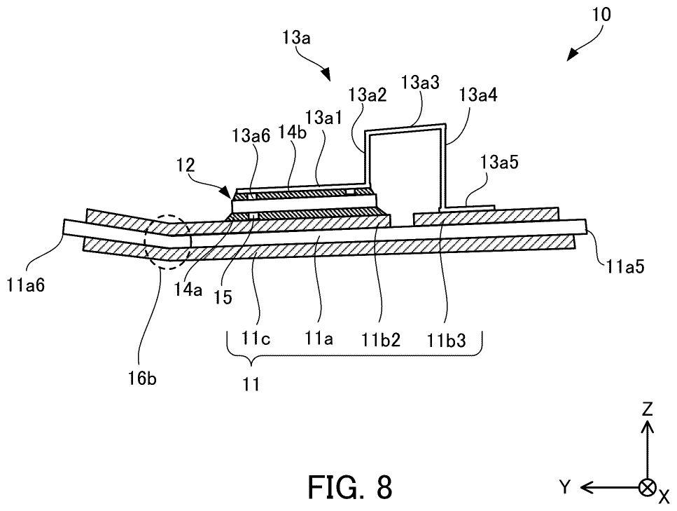

FIGS. 5 to 8 are first to fourth side views of a semiconductor unit included in the semiconductor device according to the embodiment. FIG. 5 is a side view of the semiconductor unit 10 of FIG. 3, as seen in the −Y direction, and FIG. 6 is a side view of the semiconductor unit 10 of FIG. 3, as seen in the −X direction. FIG. 7 is a side view of the semiconductor unit 10 of FIG. 3, as seen in the +Y direction, and FIG. 8 is a side view of the semiconductor unit 10 of FIG. 3, as seen in the +X direction. FIGS. 5 to 8 schematically illustrate warping. Although FIGS. 5 to 8 provide the side views, the support parts 15 and bosses 13a6 and 13b6 (these reference numerals may be omitted) are illustrated for visibility. The warping in FIGS. 5 to 8 may be illustrated larger than the actual one.

For example, refer to FIG. 5 that is a side view of the semiconductor unit 10 as seen in the −Y direction. The area where the wiring board 11b1 is formed is approximately flat. The area where the wiring board 11b2 is formed is distorted in the −Z direction relative to the area where the wiring board 11b1 is formed. Furthermore, at the vertex 16c near the center of the area where the wiring board 11b2 is formed, the insulated circuit substrate 11 is warped in a downward convex shape with the rear surface (on the −Z-direction side) thereof facing downward. In this case, the semiconductor chip 12 is located above the vertex 16c so as to be substantially parallel to the wiring board 11b2.

Refer now to FIG. 6 that is a side view of the semiconductor unit 10 as seen in the −X direction. The area where the wiring board 11b1 is formed is entirely warped in a downward convex shape with the vertex 16d as an extreme point. In this case, the side of the rear surface of the semiconductor chip 12 where the vertex 16d is located is supported by the support parts 15, so that the semiconductor chip 12 is substantially parallel to the wiring board 11b1.

Refer now to FIG. 7 that is a side view of the semiconductor unit 10 as seen in the +Y direction. The area where the wiring board 11b1 is formed is approximately flat. The area where the wiring board 11b3 is formed is warped in a downward convex shape with the vertex 16a located slightly in the −X direction from the center of this area.

Refer now to FIG. 8 that is a side view of the semiconductor unit 10 as seen in the +X direction. The area where the wiring board 11b2 is formed is entirely warped in a downward convex shape with the vertex 16b as an extreme point. In this case, the side of the rear surface of the semiconductor chip 12 where the vertex 16b is located is supported by the support parts 15, so that the semiconductor chip 12 is substantially parallel to the wiring board 11b2.

Note that the vertices 16a, 16b, 16c, and 16d of the warping do not necessarily occur simultaneously at these positions, and at least one vertex may occur.

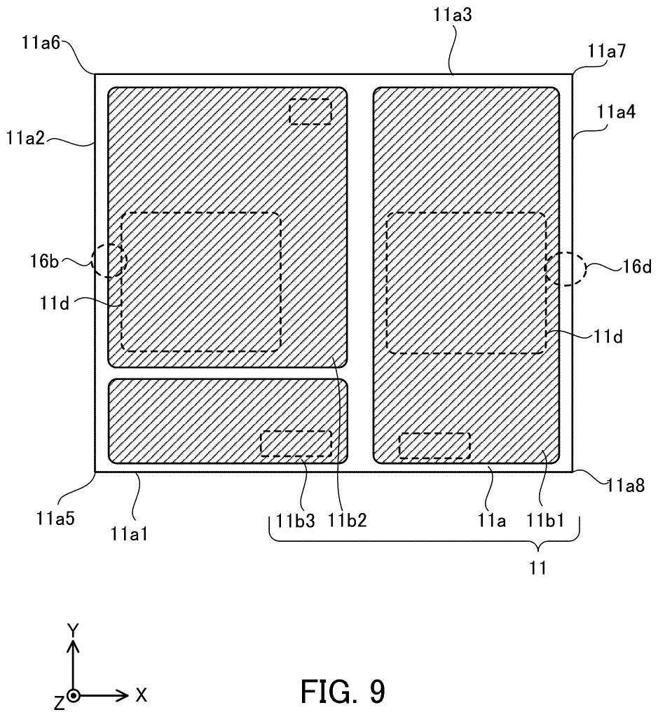

The following describes another case where the vertices of warping occur at positions that are different from those illustrated in FIG. 4, in the side surfaces 11a2 and 11a4 in the insulated circuit substrate 11. More specifically, the following describes a case where the vertices 16b and 16d of the warping occur at the centers of the side surfaces 11a2 and 11a4 in the insulated circuit substrate 11, respectively, with reference to FIGS. 9 to 11.

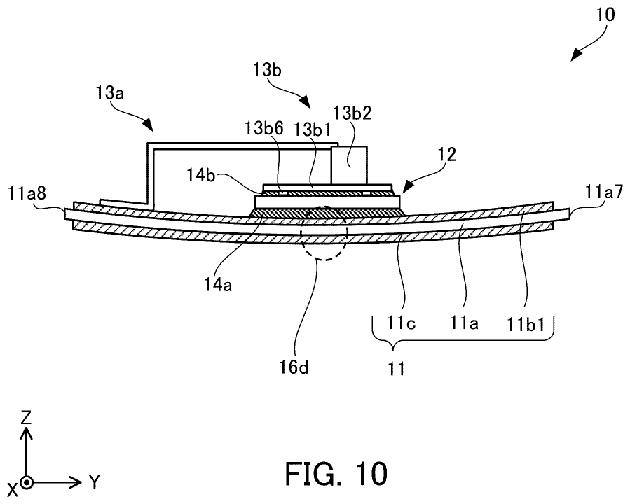

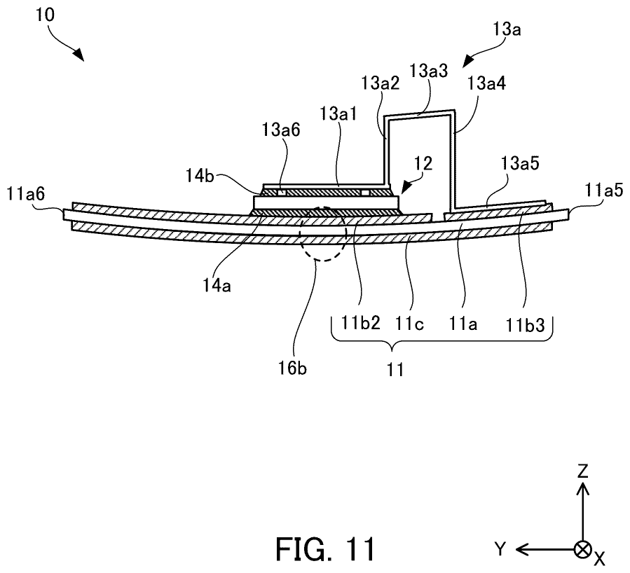

FIG. 9 is a plan view of the insulated circuit substrate included in the semiconductor device according to the embodiment and illustrates different warping. FIG. 10 is a second side view of the semiconductor unit with the different warping, which is included in the semiconductor device according to the embodiment. FIG. 11 is a fourth side view of the semiconductor unit with the different warping, which is included in the semiconductor device according to the embodiment. In this connection, FIG. 9 corresponds to FIG. 4 and illustrates a case where the vertices of warping occur at positions (at the center of the side surfaces 11a2 and 11a4) different from those illustrated in FIG. 4, in the side surfaces 11a2 and 11a4 in the insulated circuit substrate 11. FIG. 10 corresponds to FIG. 6 and provides a side view of the semiconductor unit 10 as seen in the −X direction. FIG. 11 corresponds to FIG. 8 and provides a side view of the semiconductor unit 10 as seen in the +X direction. FIGS. 10 and 11 illustrate the warping schematically. Although FIGS. 10 and 11 provide the side views, the bosses 13a6 and 13b6 (these reference numerals may be omitted) are illustrated for visibility. The warping in FIGS. 10 and 11 may be illustrated larger than the actual one.

As illustrated in FIG. 9, the vertex 16b of the warping occurs at the center in the ±Y directions of the side surface 11a2 in the insulated circuit substrate 11 included in the semiconductor unit 10. In addition, the vertex 16d of the warping occurs at the center in the ±Y directions of the side surface 11a4 in the insulated circuit substrate 11 included in the semiconductor unit 10. Note that the vertices 16b and 16d of the warping do not necessarily occur simultaneously at these positions, and at least one vertex may occur. In addition, in this case, support parts 15 are not necessarily provided in the bonding area 11d of the wiring board 11b2 of the insulated circuit substrate 11.

Refer to FIG. 10 that is a side view of the semiconductor unit 10 as seen in the −X direction. The area where the wiring board 11b1 is formed is warped in a downward convex shape with the vertex 16d located near the center of the area. In this case, the approximate center of the semiconductor chip 12 is located directly above the vertex 16d, and the semiconductor chip 12 is substantially parallel to the wiring board 11b1.

Refer now to FIG. 11 that is a side view of the semiconductor unit 10 as seen in the +X direction. The area where the wiring board 11b2 is formed is warped in a downward convex shape with the vertex 16b located near the center of the area. In this case, the approximate center of the semiconductor chip 12 is located directly above the vertex 16b, and the semiconductor chip 12 is substantially parallel to the wiring board 11b2.

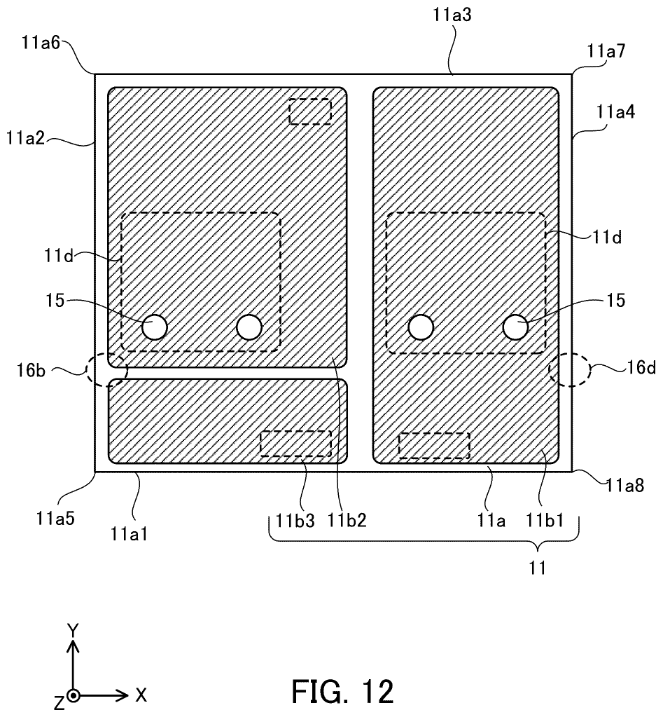

The following describes yet another case where the vertices of warping occur at positions that are different from those illustrated in FIG. 4 and FIG. 9, in the side surfaces 11a2 and 11a4 in the insulated circuit substrate 11. More specifically, the following describes a case where the vertices 16b and 16d of the warping occur at positions closer to the side surface 11a1 in the side surfaces 11a2 and 11a4 in the insulated circuit substrate 11, respectively, with reference to FIGS. 12 to 14.

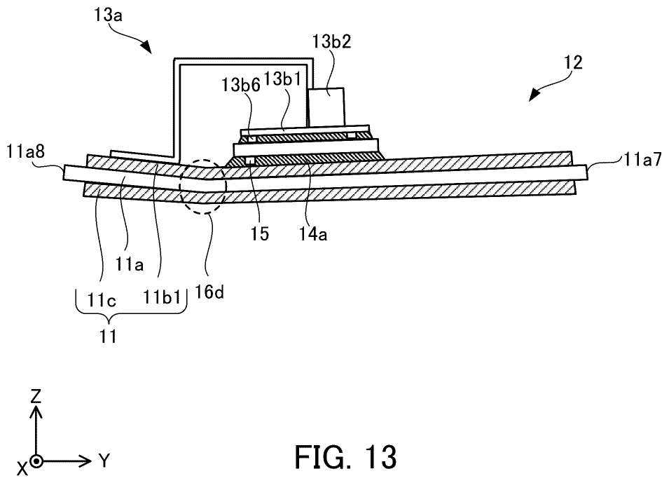

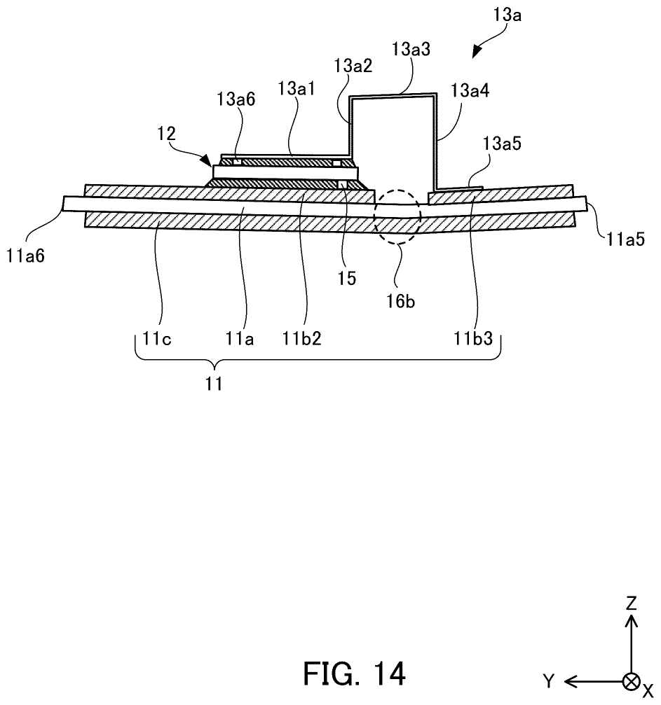

FIG. 12 is a plan view of the insulated circuit substrate included in the semiconductor device according to the embodiment and illustrates different warping. FIG. 13 is a second side view of the semiconductor unit with the different warping, which is included in the semiconductor device according to the embodiment. FIG. 14 is a fourth side view of the semiconductor unit with the different warping, which is included in the semiconductor device according to the embodiment. In this connection, FIG. 12 corresponds to FIGS. 4 and 9 and illustrates a case where the vertices of warping occur at positions (closer to the side surface 11a1 in the side surfaces 11a2 and 11a4) different from those illustrated in FIGS. 4 and 9 in the side surfaces 11a2 and 11a4 in the insulated circuit substrate 11. FIG. 13 corresponds to FIGS. 6 and 10 and provides a side view of the semiconductor unit 10 as seen in the −X direction. FIG. 14 corresponds to FIGS. 8 and 11 and provides a side view of the semiconductor unit 10 as seen in the +X direction. FIGS. 13 and 14 illustrate the warping schematically. Although FIGS. 13 and 14 provide the side views, the support parts 15 and bosses 13a6 and 13b6 (these reference numbers may be omitted) are illustrated for visibility. The warping in FIGS. 13 and 14 may be illustrated larger than the actual one.

As illustrated in FIG. 12, the vertex 16b of the warping occurs between the wiring boards 11b2 and 11b3 in the side surface 11a2 in the insulated circuit substrate 11 included in the semiconductor unit 10. In addition, the vertex 16d of the warping occurs at a position opposite to the vertex 16b in the side surface 11a4 in the insulated circuit substrate 11 included in the semiconductor unit 10.

In this connection, the vertices 16b and 16d of the warping do not necessarily occur simultaneously at these positions, and at least one vertex may occur.

A plurality of support parts 15 may be formed on the side of the bonding area 11d of the wiring board 11b2 of the insulated circuit substrate 11 where the vertex 16b is located. In this case, the plurality of support parts 15 may be arranged parallel to the side surface 11a1.

In addition, a plurality of support parts 15 may be formed on the side of the bonding area 11d of the wiring board 11b1 of the insulated circuit substrate 11 where the vertex 16d is located. In this case, the plurality of support parts 15 may be arranged parallel to the side surface 11a1.

Refer to FIG. 13 that is a side view of the semiconductor unit 10 as seen in the −X direction. The area where the wiring board 11b1 is formed is entirely warped in a downward convex shape with the vertex 16d as an extreme point. In this case, the side of the rear surface of the semiconductor chip 12 where the vertex 16d is located is supported by the support parts 15, so that the semiconductor chip 12 is substantially parallel to the wiring board 11b1.

Refer now to FIG. 14 that is a side view of the semiconductor unit 10 as seen in the +X direction. The area between the wiring boards 11b2 and 11b3 is entirely warped in a downward convex shape with the vertex 16b as an extreme point. In this case, the side of the rear surface of the semiconductor chip 12 where the vertex 16b is located is supported by the support parts 15, so that the semiconductor chip 12 is substantially parallel to the wiring board 11b2.

Note that the vertices 16b and 16d of the warping do not necessarily occur simultaneously at the positions illustrated in FIGS. 4, 9, and 12, in the side surfaces 11a2 and 11a4 in the insulated circuit substrate 11. These vertices 16b and 16d may occur separately. Moreover, the support parts 15 may be provided in any combination according to the positions of the vertices 16b and 16d of warping.

For example, in the case where only the vertex 16b occurs or only the vertex 16d occurs, the support parts 15 are provided on either the wiring board 11b1 or 11b2, depending on the position of the vertex 16b or 16d. For example, in the case where the vertices 16b and 16d occur simultaneously in a diagonal positional relationship (such as the vertex 16b in FIG. 4 and the vertex 16d in FIG. 12, or the vertex 16b in FIG. 12 and the vertex 16d in FIG. 4), the support parts 15 in the bonding area 11d of the wiring board 11b1 and the support parts 15 in the bonding area 11d of the wiring board 11b2 are provided diagonally.

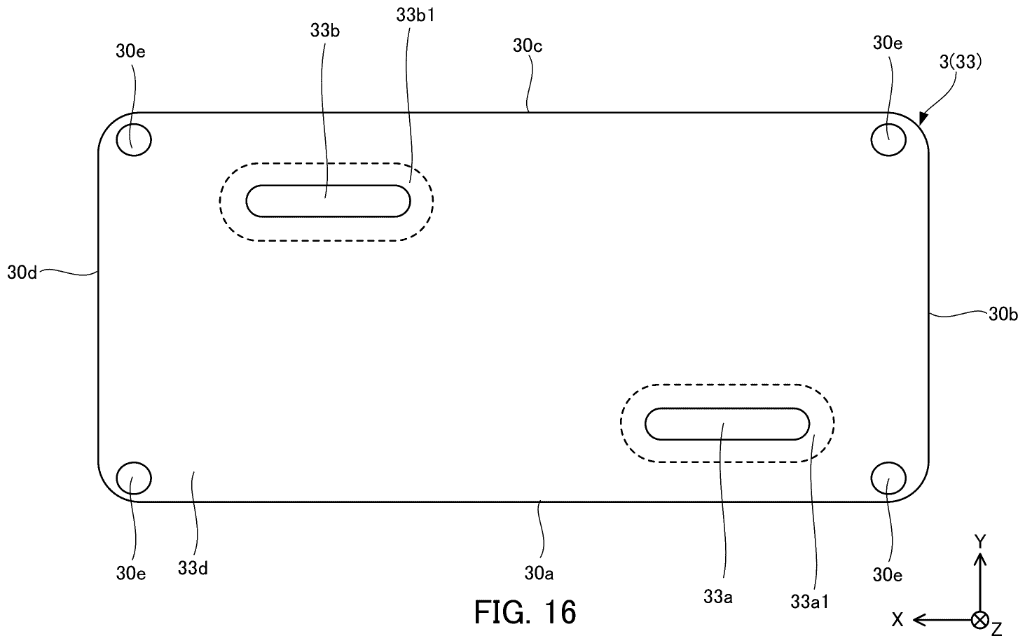

The following describes the cooling device with reference to FIGS. 15 and 16. FIG. 15 is a sectional view of the semiconductor device according to the embodiment.

FIG. 16 illustrates the back surface of the cooling device included in the semiconductor device according to the embodiment. Note that the sectional view of FIG. 15 is a view taken along the dash-dotted line X-X in FIG. 1. FIG. 16 illustrates the back side of the semiconductor device 1 in FIG. 1, rotated around a central line passing through the centers of the outer wall surfaces 21a and 21c.

The cooling device 3 has the inlet 33a for allowing coolant to flow inside and the outlet 33b for discharging the coolant that has circulated internally. The cooling device 3 cools the semiconductor unit 10 by discharging the heat from the semiconductor unit 10 via the coolant. Examples of the coolant used here include water, antifreeze (ethylene glycol solution), and long-life coolant. In addition, the cooling device 3 may be equipped with a pump and a heat dissipation device (radiator). The pump circulates the coolant in the cooling device 3 by flowing the coolant into the inlet 33a and re-flowing the coolant that has flowed out of the outlet 33b back into the inlet 33a. The heat dissipation device receives the coolant discharged from the cooling device 3 and dissipates the heat of the coolant, to which the heat of the semiconductor unit 10 has been transferred, to the outside.

This cooling device 3 has the top plate 31, a side wall 32 connected in a loop shape to the rear surface of the top plate 31, and a cooling bottom plate 33 that is positioned opposite the top plate 31 and that is connected to the rear surface of the side wall 32. The top plate 31 is rectangular, with the long sides and short sides on the four sides thereof in plan view, and a fastening hole is formed in each of the four corners thereof. In plan view, the corners of the top plate 31 may be rounded. The semiconductor units 10a, 10b, and 10c are bonded along the ±X directions to the front surface of the top plate 31. The side wall 32 is formed in a continuous loop shape on the rear surface of the top plate 31. A plurality of heat dissipation fins 34 are formed in areas of the rear surface of the top plate 31 corresponding to the areas where the semiconductor units 10a, 10b, and 10c are disposed.

The cooling bottom plate 33 is flat plate-shaped and has the same shape as the top plate 31 in plan view. The cooling bottom plate 33 is rectangular, with long sides 30a and 30c and short sides 30b and 30d on the four sides thereof in plan view. A fastening hole 30e is formed in each of the four corners so as to correspond to those formed in the top plate 31. In addition, the corners of the cooling bottom plate 33 may also be rounded. The cooling bottom plate 33 has a front surface and a back surface 33d, which are parallel to each other. The back surface 33d of the cooling bottom plate 33 is a flat surface without any steps, so as to form a single plane. Furthermore, the back surface 33d of the cooling bottom plate 33 may also be parallel to the front surface of the top plate 31. The inlet 33a for allowing the coolant to flow therein and the outlet 33b through which the coolant flows out are formed in the back surface 33d of the cooling bottom plate 33. Seal areas 33a1 and 33b1 are provided around the inlet 33a and outlet 33b on the back surface 33d of the cooling bottom plate 33 so as to surround the inlet 33a and outlet 33b. A distribution head is attached to each of the inlet 33a and outlet 33b via an annular rubber gasket, within the seal areas 33a1 and 33b1 surrounding the inlet 33a and outlet 33b. A distribution pipe connected to the pump is attached to each distribution head.

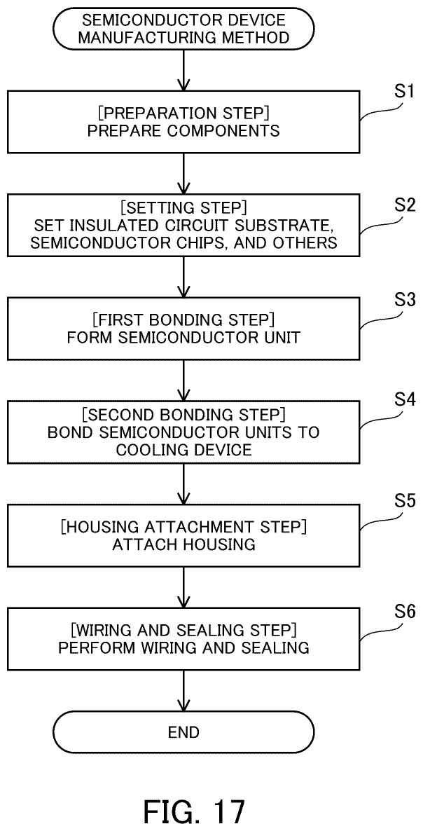

The following describes a method of manufacturing the above-described semiconductor device 1 with reference to FIG. 17. FIG. 17 is a flowchart illustrating a semiconductor device manufacturing method according to the embodiment. First, a preparation step is executed (step S1), in which the components of the semiconductor device 1 are prepared. The components include, for example, the semiconductor chips 12, the insulated circuit substrate 11, the lead frames 13a and 13b, the housing 20, the cooling device 3, and the sealing material of the sealing member 27. Other components that are needed for manufacturing the semiconductor device 1 are also prepared. In addition, manufacturing equipment and manufacturing jigs that are needed for manufacturing the semiconductor device 1 may also be prepared.

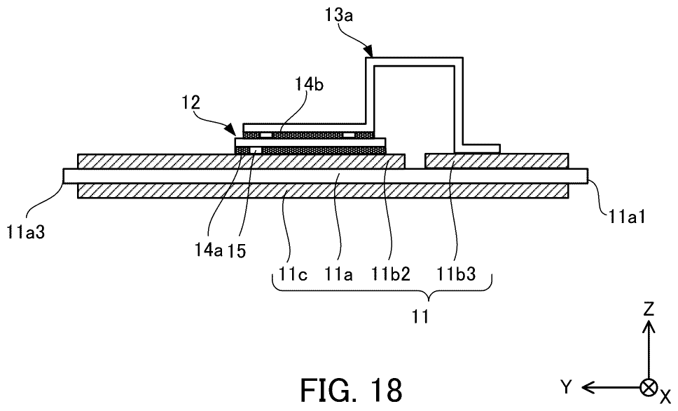

Then, a setting step is executed (step S2), in which the semiconductor chips 12 are set on the insulated circuit substrate 11, and then the lead frames 13a and 13b are sequentially set. A structure obtained as a result of this setting step will be described with reference to FIG. 18. FIG. 18 is a view for describing the structure obtained by the setting step included in the semiconductor device manufacturing method according to the embodiment. In this connection, FIG. 18 is a sectional view of the structure in which the insulated circuit substrate 11, semiconductor chips 12, and lead frames 13a and 13b are set in order. This sectional view corresponds to a view taken along the dash-dotted line X-X of FIG. 3.

As illustrated in FIG. 18, a semiconductor chip 12 is placed on the wiring board 11b2 of the insulated circuit substrate 11 via the bonding material 14a in the setting step. Examples of the bonding material 14a before curing used here include a solder paste or a solder plate. At this time, support parts 15 are arranged on the +Y-direction side of the semiconductor chip 12 between the rear surface of the semiconductor chip 12 and the wiring board 11b2. That is, the rear surface of the semiconductor chip 12 is supported by the support parts 15.

In addition, the main electrode bonding portion 13a1 of the lead frame 13a is placed on the main electrode 12b of the semiconductor chip 12 via the bonding material 14b. Examples of the bonding material 14b before curing used here include a solder paste and a solder plate. At this time, the main electrode bonding portion 13a1 is placed on the main electrode 12b of the semiconductor chip 12 via the bosses 13a6 formed on the rear surface of the main electrode bonding portion 13a1. The wiring bonding portion 13a5 of the lead frame 13a is placed on the wiring board 11b3.

Next, a first bonding step is executed (step S3), in which the structure obtained at step S2 is heated to bond the components to thereby form a semiconductor unit 10. More specifically, the structure illustrated in FIG. 18 is heated, so that the bonding materials 14a and 14b are melted and are then cured. By doing so, the semiconductor chip 12 is bonded to the wiring board 11b2 of the insulated circuit substrate 11 via the bonding material 14a. In addition, the main electrode bonding portions 13a1 and 13b1 of the lead frames 13a and 13b are bonded to the main electrodes 12b of the semiconductor chips 12 via the bonding material 14b. In this connection, the wiring bonding portions 13a5 and 13b5 of the lead frames 13a and 13b are joined to the wiring boards 11b3 and 11b2, respectively, by ultrasonic welding, for example. Due to the heating in the first bonding step, warping occurs in the insulated circuit substrate 11, as illustrated in FIGS. 5 to 8. The warping in the insulated circuit substrate 11 will be described in detail later.

After that, a second bonding step is executed (step S4), in which thus obtained semiconductor units 10 are bonded to the top plate 31 of the cooling device 3. The semiconductor units 10 are bonded to the top plate 31 of the cooling device 3 via a bonding material such as a brazing material or a thermal interface material, as previously described. Then, a housing attachment step is executed (step S5), in which the housing 20 is attached to the cooling device 3. More specifically, the housing 20 is attached to the top plate 31 of the cooling device 3 to which the semiconductor units 10 have been bonded, using an adhesive, so that the semiconductor units 10 are housed in the unit housing spaces 21e, 21f, and 21g of the housing 20, respectively. It is noted that, for example, the first bonding step and the second bonding step may be executed simultaneously.

Then, a wiring and sealing step is executed (step S6), in which wiring is applied to the semiconductor units 10 and the sealing member 27 is applied to seal the unit housing spaces 21e, 21f, and 21g. The inner ends of the first connection terminals 22a, 22b, and 22c, which extend from the housing 20 into the unit housing spaces 21e, 21f, and 21g, are joined respectively to the wiring boards 11b1 of the insulated circuit substrates 11 in the semiconductor units 10 by, for example, ultrasonic welding. Similarly, the inner ends of the second connection terminals 23a, 23b, and 23c are bonded respectively to the wiring boards 11b3 of the insulated circuit substrates 11 in the semiconductor units 10. Yet similarly, the inner ends of the U-phase output terminal 24a, V-phase output terminal 24b, and W-phase output terminal 24c are bonded respectively to the wiring boards 11b2 of the insulated circuit substrates 11 in the semiconductor units 10. Furthermore, the inner ends of the control terminals 25a, 25b, and 25c provided in the housing 20 are connected respectively to the control electrodes 12a of the semiconductor chips 12 using the wires 26. The sealing member 27 is then applied to the unit housing spaces 21e, 21f, and 21g to seal the semiconductor units 10. Through the above steps, the semiconductor device 1 illustrated in FIGS. 1 and 2 is obtained.

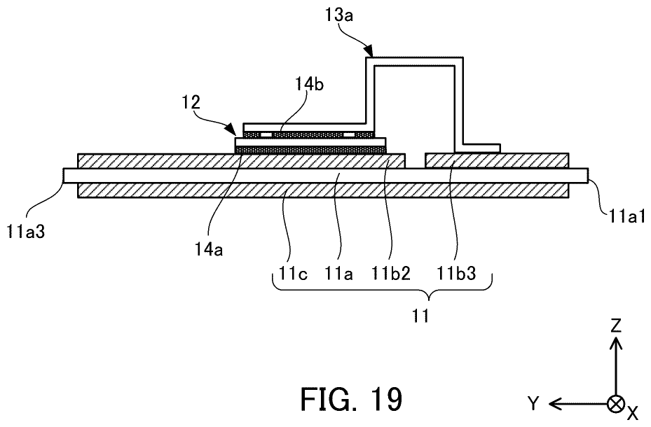

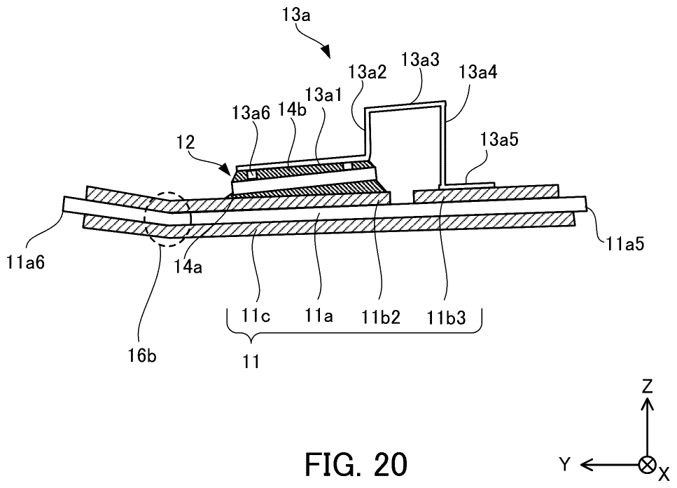

The following describes a semiconductor device according to a reference example. The semiconductor device in this reference example has the same components as the semiconductor device 1, except the support parts 15. In addition, the semiconductor device is manufactured using the manufacturing method of FIG. 17, as with the semiconductor device 1. The following describes the setting step (step S2) and first bonding step (step S3) of the manufacturing method for this reference example, with reference to FIGS. 19 and 20. FIG. 19 is a view for describing a structure obtained by the setting step of the semiconductor device manufacturing method according to the reference example. FIG. 20 is a view for describing the first bonding step of the semiconductor device manufacturing method according to the reference example.

The setting step is executed (step S2), in which the semiconductor chips 12 are set on the insulated circuit substrate 11, and then the lead frames 13a and 13b are sequentially set. As a result, as illustrated in FIG. 19, a semiconductor chip 12 is placed on the wiring board 11b2 of the insulated circuit substrate 11 via only the bonding material 14a. In addition, the main electrode bonding portion 13a1 of the lead frame 13a is placed on the main electrode 12b of the semiconductor chip 12 via the bonding material 14b.

After that, the first bonding step is executed (step S3), in which these components are heated and bonded to form a semiconductor unit 10. As described earlier, warping occurs in the insulated circuit substrate 11 due to the heating. For example, the wiring boards 11b1 to 11b3 and the metal plate 11c have different coefficients of linear expansion from the insulating plate 11a. In addition, the volume of the wiring boards 11b1 to 11b3 formed on the front surface of the insulating plate 11a is different from that of the metal plate 11c formed on the rear surface of the insulating plate 11a. In the reference example here, an example in which warping occurs as illustrated in FIGS. 5 to 8 will be described. More specifically, this example is that the warping occurs with the vertices 16a to 16d as extreme points in the side surfaces 11a1 to 11a4 of the insulated circuit substrate 11 of FIG. 4.

For example, the warping occurs in the semiconductor unit 10, as illustrated in a sectional view of FIG. 20 taken along the dash-dotted line X-X of FIG. 3 (corresponding to the side view as seen in the +X direction). More specifically, the insulated circuit substrate 11 is warped in a downward convex shape with the vertex 16b as an extreme point. The bonding materials 14a and 14b are melted due to the heating. Since the wiring board 11b2 is tilted due to the warping, the semiconductor chip 12 placed in the bonding area 11d of the tilted wiring board 11b2 is also tilted because the bonding material 14a is melted during the heating. In this connection, the bosses 13a6 formed on the rear surface of the main electrode bonding portion 13a1 of the lead frame 13a enables the main electrode bonding portion 13a1 to keep in substantially parallel to the semiconductor chip 12.

If the bonding material 14a is cured to thereby bond the semiconductor chip 12 to the wiring board 11b2 while the semiconductor chip 12 is in the tilted state, the thickness of the bonding material 14a becomes uneven with both thin and thick areas. More specifically, the bonding material 14a is thin on the side near the vertex 16b, and is thick on the side farther from the vertex 16b.

In the thin area of the bonding material 14a, cracks are more likely to occur due to external stress. In addition, the thick area of the bonding material 14a exhibits lower heat dissipation than the thin area thereof. The bonding material 14a with this uneven thickness may decrease the reliability of the semiconductor device.

In this connection, for example, referring to FIG. 10 that is a side view of the semiconductor unit 10 as seen in the −X direction, the vertex 16d occurs directly below the center of the semiconductor chip 12. In this case, the semiconductor chip 12 is substantially parallel to the wiring board 11b1, so that the bonding material 14a becomes approximately uniform in thickness, which reduces the risk of causing cracks.

Considering the above, the semiconductor device 1 described above includes a semiconductor chip 12 and the insulated circuit substrate 11 that includes the wiring board 11b2 in the front surface thereof and that is warped in a downward convex shape with the rear surface of the insulated circuit substrate 11 thereof facing downward. The semiconductor chip 12 is bonded via the bonding material 14a to the bonding area 11d defined on the upper surface of the wiring board 11b2 that is tilted in the front surface of the insulated circuit substrate 11 due to the warping. At this time, the semiconductor chip 12 is bonded to the bonding area 11d while the edge portion of the rear surface of the semiconductor chip 12 located on the side where the vertex 16b of the warping in the insulated circuit substrate 11 is located is supported by the support parts 15 provided in the bonding area 11d. The support parts 15 allow the semiconductor chip 12 to be substantially parallel to the bonding area 11d of the wiring board 11b2, so that the bonding material 14a becomes approximately uniform in thickness. This reduces the risk of causing cracks in the bonding material 14a and minimizes variations in thermal conductivity in the bonding material 14a. Therefore, a decrease in the reliability of the semiconductor device 1 is prevented. The support parts 15 are preferably formed positions corresponding to two corners of the at semiconductor chip 12 located on the side where the vertex 16b is located, in the bonding area 11d defined on the upper surface of the wiring board 11b2. In this configuration, the support parts 15 allow the semiconductor chip 12 to be substantially parallel to the bonding area 11d of the wiring board 11b2, so that the semiconductor chip 12 is able to have a more stable posture of being substantially parallel to the bonding area 11d.

In this connection, as illustrated in FIG. 4, the insulated circuit substrate 11 is warped not only with the vertex 16b but also with the vertices 16a, 16c, and 16d. Furthermore, the warping also occurs with the vertices 16b and 16d, as illustrated in FIG. 12. As described earlier, the vertices 16b and 16d illustrated in FIG. 9 are located directly below the center of the semiconductor chip 12 disposed in the bonding area 11d in the side view, and therefore have little effect on the tilting of the semiconductor chip 12.

Referring to FIG. 4 of the present embodiment, the support parts 15 are provided to ensure that the semiconductor chip 12, which is placed in the bonding area 11d defined on the upper surface of the wiring board 11b2 that is tilted due to the downward convex warping with the vertex 16b as an extreme point in a side view, is substantially parallel to the wiring board 11b2.

In addition, in FIG. 4, on the wiring board 11b2 that is tilted due to the downward convex warping with the vertices 16a and 16c as extreme points in a side view, support parts 15 may be provided on the side of the bonding area 11d of the wiring board 11b2 where the side surface 11a4 is located. Furthermore, support parts 15 may appropriately be provided in the bonding area 11d according to the orientation of the warping in the wiring board 11b2 to ensure that the semiconductor chip 12 is substantially parallel to the wiring board 11b2.

Furthermore, referring to FIG. 4 of the present embodiment, the support parts 15 are provided to ensure that the semiconductor chip 12, which is placed in the bonding area 11d defined on the upper surface of the wiring board 11b1 that is tilted due to the downward convex warping with the vertex 16d as an extreme point in a side view, is substantially parallel to the wiring board 11b1.

In addition, referring to FIG. 12 of the present embodiment, the support parts 15 are provided to ensure that the semiconductor chips 12, which are placed in the bonding areas 11d of the upper surfaces of the wiring boards 11b1 and 11b2 that are tilted due to the downward convex warping with the vertices 16b and 16d as extreme points in a side view, are substantially parallel to the wiring boards 11b1 and 11b2.

The following describes various modifications of a support part 15. The following describes, as an example, a case where warping occurs with the vertex 16b as an extreme point, as illustrated in FIG. 4. The modifications of the support part 15 described below are also applicable to cases where warping occurs with the vertex 16b of FIG. 9 as an extreme point and where warping occurs with the vertices 16b and 16d of FIG. 12 as extreme points.

### Modification 1

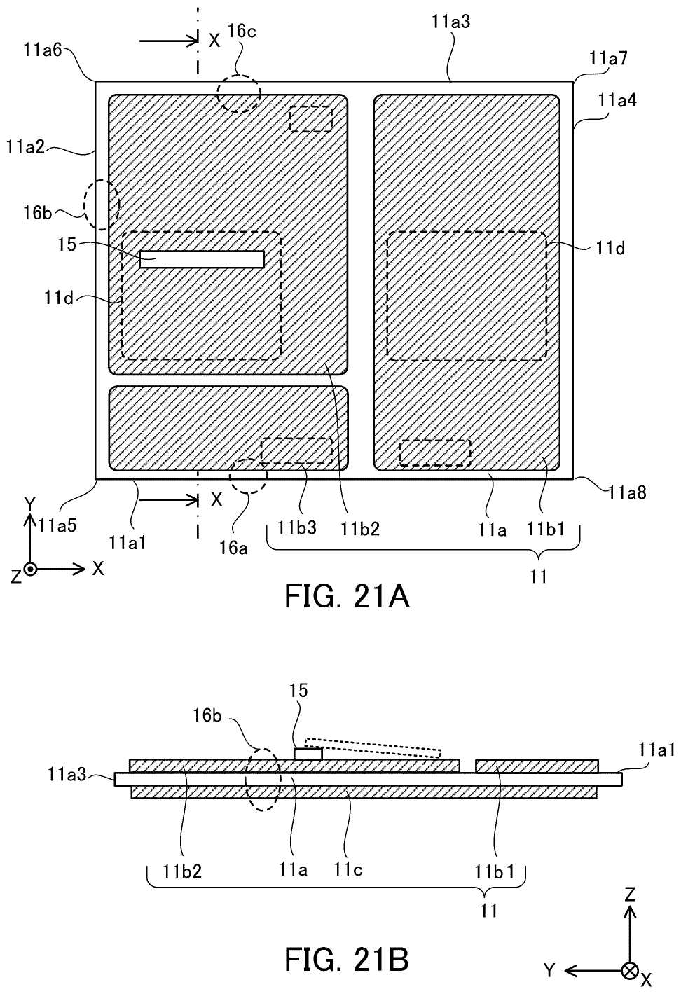

A support part 15 according to Modification 1 will be described with reference to FIGS. 21A and 21B. FIGS. 21A and 21B illustrate an insulated circuit substrate that is included in the semiconductor device according to the embodiment (Modification 1). Specifically, FIG. 21A is a plan view of the insulated circuit substrate 11 with the support part 15, and FIG. 21B is a sectional view taken along the dash-dotted line X-X of FIG. 21A. The insulated circuit substrate 11 illustrated in FIGS. 21A and 21B is not yet warped, and the position where the vertex 16b is expected to occur is indicated by a dashed-line circle in FIG. 21B. In FIG. 21B, only the vertex 16b is illustrated. In addition, in FIG. 21B, a semiconductor chip 12, which is disposed in the bonding area 11d where the support part 15 is provided, is indicated by a dashed line.

In Modification 1, the support part 15 is provided on the side of the bonding area 11d of the wiring board 11b2 where the vertex 16b occurs in the side view seen in the +X direction. The support part 15 of Modification 1 has a rod shape in plan view. The support part 15 is provided along the side surface 11a3 on the side of the bonding area 11d of the wiring board 11b2 where the side surface 11a3 is located. The support part 15 may have a rectangular, triangular, or semicircular cross section in the Y-Z plane. In this example, the support part 15 is illustrated in a rectangular cross section. The height of the support part 15 in the ±Z directions is determined in advance according to an expected degree of warping.

When the insulated circuit substrate 11 is warped in a downward convex shape with the vertex 16b as an extreme point, the above wiring board 11b2 enables the semiconductor chip 12 to be substantially parallel to the wiring board 11b2. Although only one support part 15 is illustrated in Modification 1, the number of support parts 15 is not limited to one. A plurality of support parts 15 may be arranged in multiple rows parallel to the side surfaces 11a1 and 11a3.

In addition, the support part 15 is not limited to having the continuous rod shape illustrated in FIGS. 21A and 21B. One or more support parts 15 may be arranged in a dashed pattern in a single row or multiple rows, parallel to the side surfaces 11a1 and 11a3.

In addition, the above support part 15 may be provided along the side surface 11a4 in the bonding area 11d of the wiring board 11b2, depending on a warping pattern that is, for example, downward convex warping with the vertices 16a and 16c as extreme points.

### Modification 2

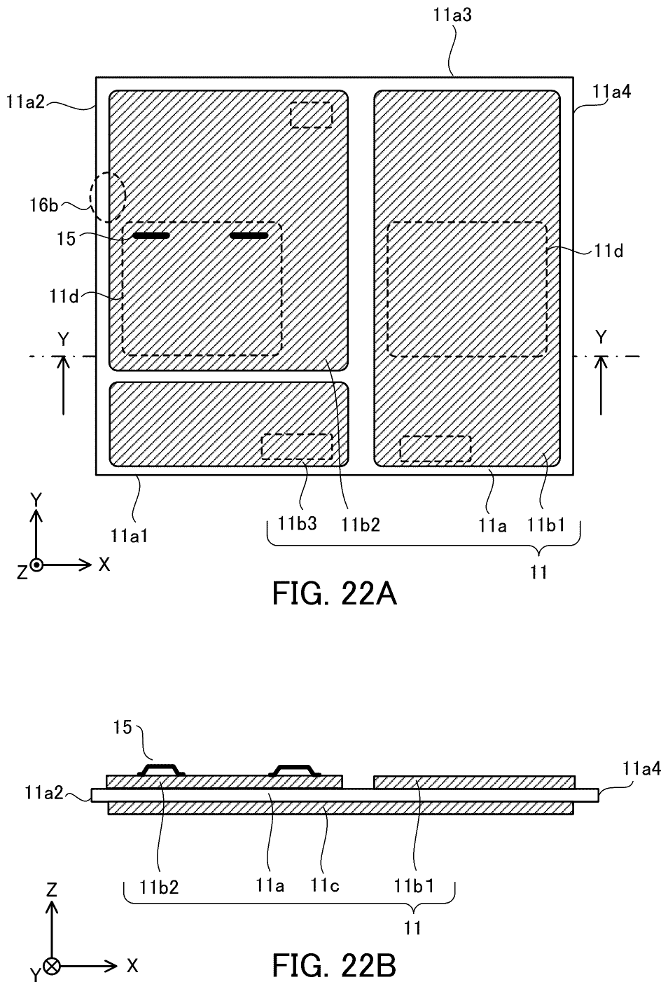

Support parts 15 according to Modification 2 will now be described with reference to FIGS. 22A and 22B. FIGS. 22A and 22B illustrate an insulated circuit substrate that is included in the semiconductor device according to the embodiment (Modification 2). Specifically, FIG. 22A is a plan view of the insulated circuit substrate 11 with the support parts 15, and FIG. 22B is a sectional view taken along the dash-dotted line Y-Y of FIG. 22A. The insulated circuit substrate 11 illustrated in FIGS. 22A and 22B is also not yet warped, and the position where the vertex 16b is expected to occur is indicated by a dashed-line circle in FIG. 22A.

In Modification 2, the support parts 15 are provided on the side of the bonding area 11d of the wiring board 11b2 where the vertex 16b occurs in the side view seen in the +X direction. The support parts 15 of Modification 2 are formed of wires. Here, the wires are formed near the corners of the bonding area 11d of the wiring board 11b2 located on the side where the vertex 16b is located in the side view. In Modification 2, the wires are arranged parallel to the side surfaces 11a1 and 11a3. In addition, the heights of the support parts 15 in the +Z directions are determined in advance according to an expected degree of warping.

When the insulated circuit substrate 11 is warped in a downward convex shape with the vertex 16b as an extreme point, the above wiring board 11b2 enables the semiconductor chip 12 to be substantially parallel to the wiring board 11b2. The support parts 15 are preferably formed along the side of the semiconductor chip 12 located on the side where the vertex 16b is located, in the bonding area 11d of the wiring board 11b2. The support parts 15 are also preferably formed at positions corresponding to two corners of the semiconductor chip 12 located on the side where the vertex 16b is located, in the bonding area 11d defined on the upper surface of the wiring board 11b2. The support parts 15 allow the semiconductor chip 12 to be substantially parallel to the bonding area 11d of the wiring board 11b2, so that the semiconductor chip 12 is able to have a more stable posture of being substantially parallel to the bonding area 11d. In Modification 2, two support parts 15 are arranged in a single row. However, the number of support parts 15 are not limited to two. One support part or three or more support parts may be provided to extend from the edge on the side surface 11a2 side of the bonding area 11d to the edge on the side surface 11a4 side of the bonding area 11d. Alternatively, support parts 15 may be provided in multiple rows on the side closer to the side surface 11a3. In this case, the heights of the support parts 15 in the multiple rows may be made higher as the support parts 15 approach the side surface 11a3. In addition, for example, the support parts 15 may be provided along the side surfaces 11a2 and 11a4 or diagonally across the bonding area 11d, depending on a warping pattern. The use of the wires as the support parts 15 allows for high flexibility in the arrangement, such as enabling the support parts 15 to be formed where needed.

### Modification 3

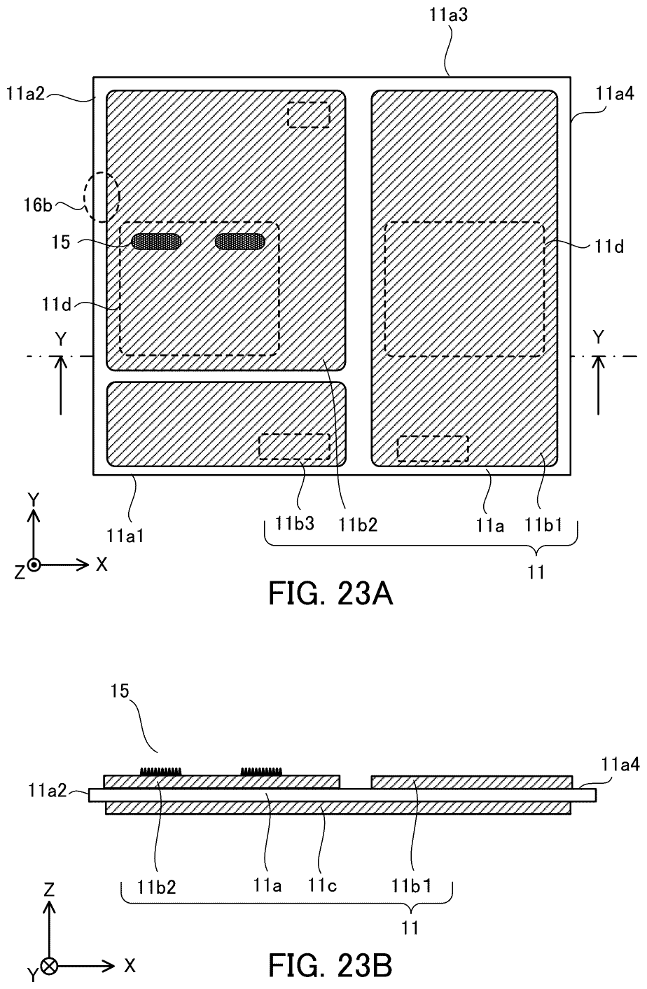

Support parts 15 according to Modification 3 will now be described with reference to FIGS. 23A and 23B. FIGS. 23A and 23B illustrate an insulated circuit substrate that is included in the semiconductor device according to the embodiment (Modification 3). Specifically, FIG. 23A is a plan view of the insulated circuit substrate 11 with the support parts 15, and FIG. 23B is a sectional view taken along the dash-dotted line Y-Y of FIG. 23A. The insulated circuit substrate 11 illustrated in FIGS. 23A and 23B is also not yet warped, and the position where the vertex 16b is expected to occur is indicated by a dashed-line circle in FIG. 23A.

In Modification 3, the support parts 15 are provided on the side of the bonding area 11d of the wiring board 11b2 where the vertex 16b occurs in the side view seen in the +X direction. In Modification 3, the support parts 15 are roughened areas formed by roughening the upper surface of the wiring board 11b2. The roughening may be achieved, for example, by laser processing, blasting, or roughened plating. The roughened support parts 15 are formed near corners of the bonding area 11d so as to be parallel to the side surfaces 11a1 and 11a3. In addition, the heights of the support parts 15 in the +Z directions are determined in advance according to an expected degree of warping.

When the insulated circuit substrate 11 is warped in a downward convex shape with the vertex 16b as an extreme point, the above wiring board 11b2 enables the semiconductor chip 12 to be substantially parallel to the wiring board 11b2. The support parts 15 are preferably formed at positions corresponding to two corners of the semiconductor chip 12 located on the side where the vertex 16b is located, in the bonding area 11d defined on the upper surface of the wiring board 11b2. In this configuration, the support parts 15 allow the semiconductor chip 12 to be substantially parallel to the bonding area 11d of the wiring board 11b2, so that the semiconductor chip 12 is able to have a more stable posture of being substantially parallel to the bonding area 11d. In Modification 3, the support parts 15 are formed at two positions and are arranged in a single row. However, the number of positions where the support parts 15 are formed is not limited to two. One position or three or more positions may be defined for the formation of the support parts 15 such that the support parts 15 are arranged in a straight line from the edge on the side surface 11a2 side of the bonding area 11d to the edge on the side surface 11a4 side of the bonding area 11d. In addition, such support parts 15 may be arranged in multiple rows, on the side closer to the side surface 11a3 in the bonding area 11d of the wiring board 11b2. In addition, for example, the support parts 15 may be provided along the side surfaces 11a2 and 11a4 or diagonally across the bonding area 11d, depending on a warping pattern. The formation of the support parts 15 by roughening allows for high flexibility in the arrangement, such as enabling the support parts 15 to be formed where needed.

### Modification 4

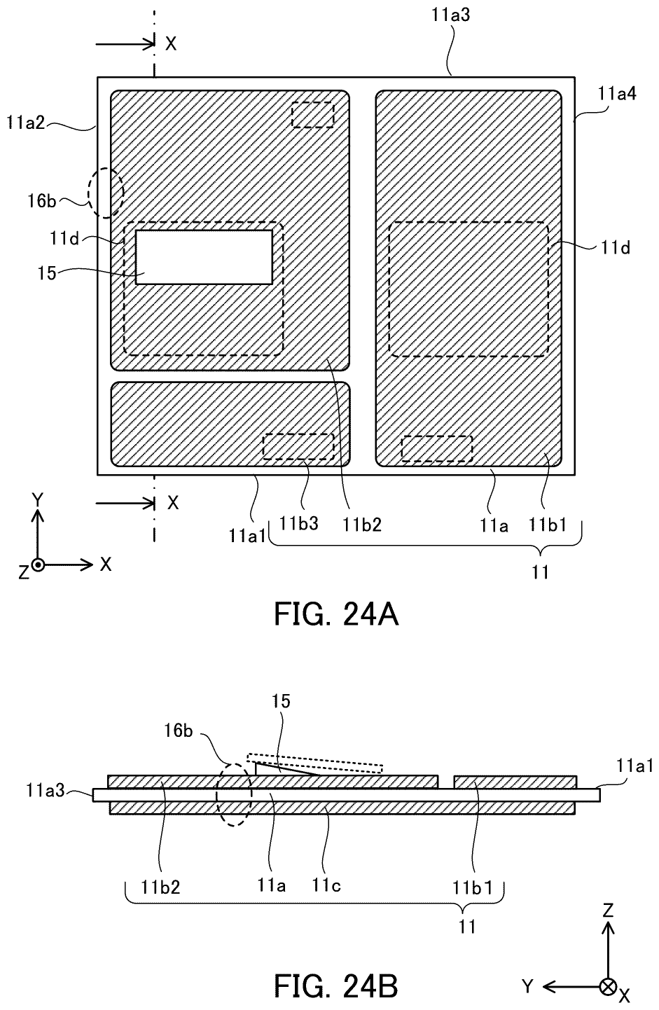

A support part 15 according to Modification 4 will now be described with reference to FIGS. 24A and 24B. FIGS. 24A and 24B illustrate an insulated circuit substrate that is included in the semiconductor device according to the embodiment (Modification 4). Specifically, FIG. 24A is a plan view of the insulated circuit substrate 11 with the support part 15, and FIG. 24B is a sectional view taken along the dash-dotted line X-X of FIG. 24A. The insulated circuit substrate 11 illustrated in FIGS. 24A and 24B is also not yet warped, and the position where the vertex 16b is expected to occur is indicated by a dashed-line circle in FIGS. 24A and 24B. In FIG. 24B, the semiconductor chip 12, which is disposed in the bonding area 11d where the support part 15 is provided, is indicated by a dashed line.

In Modification 4, the support part 15 is rectangular in plan view and is placed in the half area on the +Y-direction side of the bonding area 11d of the wiring board 11b2. The support part 15 has a sloped front surface such that its height increases toward the side where the vertex 16b occurs, in the side view of the bonding area 11d of the wiring board 11b2 seen in the +X direction. More specifically, in the side view of the bonding area 11d of the wiring board 11b2 seen in the +X direction, the support part 15 has the sloped front surface, with the side thereof closer to the vertex 16b being higher than the side thereof farther from the vertex 16b. The angle of the sloped surface of the support part 15 is determined in advance according to an expected degree of warping. In addition, the lengths of the support part 15 in the +Y directions and the +X directions are also determined in advance according to the expected degree of warping.

When the insulated circuit substrate 11 is warped in a downward convex shape with the vertex 16b as an extreme point, the above wiring board 11b2 enables the semiconductor chip 12 to be substantially parallel to the wiring board 11b2 as the rear surface of the semiconductor chip 12 is supported by the support part 15. The support part 15 is able to support the rear surface of the tilted semiconductor chip 12 stably. In addition, the support part 15 is preferably formed along the side of the semiconductor chip 12 where the vertex 16b is located, in the bonding area 11d of the wiring board 11b2. In this configuration, the support part 15 allows the semiconductor chip 12 to be substantially parallel to the bonding area 11d of the wiring board 11b2, so that the semiconductor chip 12 is able to have a more stable posture of being substantially parallel to the bonding area 11d.

In Modification 4, one support part 15 is provided along the side surfaces 11a1 and 11a3. However, the number of such sloping support parts 15 is not limited to one. A plurality of sloping support parts 15 may be arranged in a single row along the side surfaces 11a1 and 11a3. In the case where a plurality of support parts 15 are provided, the bonding material 14a fills the spaces between these support parts 15, which increases the contact area between the support parts 15 and the bonding material 14a. Thus, more reliable bonding is achieved between the bonding area 11d and the semiconductor chip 12.

The disclosed techniques make it possible to reduce the risk of causing damage to a bonding material that bonds a semiconductor chip to a wiring board, thereby preventing a decrease in the reliability of the semiconductor device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip; and
a substrate having a front surface, and a rear surface opposite to the front surface and facing downward, the substrate being warped in a downward convex shape that defines a vertex of the warping, the substrate having a wiring board at the front surface thereof, the wiring board having a bonding area defined on an upper surface thereof, which is tilted due to the warping of the substrate, wherein
the bonding area has a support part provided therein, and
the semiconductor chip is bonded to the bonding area via a first bonding material, with an edge portion of the semiconductor chip closest to the vertex of the warping supported by the support part.

2. The semiconductor device according to claim 1, wherein the semiconductor chip is substantially parallel to the bonding area of the wiring board.

3. The semiconductor device according to claim 1, wherein the support part has a projection shape.

4. The semiconductor device according to claim 3, wherein the support part is provided in plurality.

5. The semiconductor device according to claim 4, wherein
the semiconductor chip is rectangular in a plan view of the semiconductor device, and
the plurality of support parts are respectively provided at positions corresponding to two corners of the semiconductor chip.

6. The semiconductor device according to claim 1, wherein the support part has a sloped surface with a first side and a second side located farther from the vertex than the first side, the first side being higher than the second side in a side view of the semiconductor device.

7. The semiconductor device according to claim 6, wherein
the semiconductor chip is rectangular in a plan view of the semiconductor device, and
the support part is provided along a side of the semiconductor chip at which said edge portion thereof is located.

8. The semiconductor device according to claim 1, wherein the support part is a roughened area of the bonding area.

9. The semiconductor device according to claim 8, wherein the support part includes another roughened area in addition to the roughened area.

10. The semiconductor device according to claim 9, wherein
the semiconductor chip is rectangular in a plan view of the semiconductor device, and
the roughened area and the another roughened area are provided at positions corresponding to two corners of the semiconductor chip.

11. The semiconductor device according to claim 1, wherein the support part is a wire.

12. The semiconductor device according to claim 11, wherein
the semiconductor chip is rectangular in a plan view of the semiconductor device, and
the support part is provided along a side of the semiconductor chip at which said edge portion thereof is located.

13. The semiconductor device according to claim 12, wherein the support part is provided at positions corresponding to two corners of the semiconductor chip.

14. The semiconductor device according to claim 1, wherein
the semiconductor chip has a main electrode on a front surface thereof, and
the semiconductor device further includes a wiring member having a flat plate-shaped bonding portion bonded via a second bonding material to the main electrode.

15. The semiconductor device according to claim 14, wherein the bonding portion of the wiring member is substantially parallel to the front surface of the semiconductor chip.

16. The semiconductor device according to claim 14, wherein
the bonding portion has a bonding surface bonded to the main electrode of the semiconductor chip, and
the bonding surface has a projection formed therein.
